(19) United States
(12) Patent Application Publication
(10) Pub. No.: US 2015/0152258 A1
(43) Pub. Date: Jun. 4, 2015

(54) RESIN COMPOSITION FOR ENCAPSULATION AND ELECTRONIC DEVICE USING THE SAME

(71) Applicant: SUMITOMO BAKELITE CO., LTD., Tokyo (JP)

(72) Inventor: Jun-ichi Tabei, Fukuoka (JP)

(73) Assignee: SUMITOMO BAKELITE CO., LTD., Tokyo (JP)

(21) Appl. No.: 14/371,477

(22) PCT Filed: Mar. 12, 2013
(86) PCT No.: PCT/JP2013/001590

§ 371 Date: Jul. 10, 2014

(30) Foreign Application Priority Data
Mar. 16, 2012 (JP) 2012-060748
Sep. 21, 2012 (JP) 2012-207668

(51) Int. Cl. C08L 63/00; C08G 59/62; C08G 59/06; H01L 23/29

(52) U.S. Cl. CPC C08L 63/00; H01L 23/295; C08G 59/621; C08G 59/063; C08L 2203/206; C08L 2205/06

(57) ABSTRACT

The present invention provides a resin composition for encapsulating electronic elements that contains a phenol resin curing agent, an epoxy resin, and a release agent of which a 5% weight reduction temperature is equal to or higher than 240° C.; a resin composition for encapsulating electronic components that contains an epoxy resin and a release agent of which a 5% weight reduction temperature is equal to or higher than 240° C.; and a resin composition for encapsulating electronic components that contains a phenol resin curing agent, an epoxy resin, and a release agent of which a 5% weight reduction temperature is equal to or higher than 240° C., in which a glass transition temperature (Tg) of a cured material of the encapsulating resin composition is equal to or higher than 200° C., and when the cured material is heated for 1,000 hours at 200° C. in the atmosphere, a weight reduction rate of the cured material becomes equal to or lower than 0.3%; and an electronic device that includes an electronic component encapsulated with the resin composition.

### TECHNICAL FIELD

The present invention relates to a resin composition for encapsulation and an electronic device using the same. More specifically, the present invention relates to, for example, a resin composition which is for encapsulating an electronic component such as a semiconductor and an electronic device which includes the electronic component encapsulated with the resin composition.

### BACKGROUND ART

In recent years, from the viewpoint of effective utilization of electric energy and the like, a SiC/GaN power semiconductor device equipped with an element using silicon carbide (SiC) and gallium nitride (GaN) (a semiconductor device equipped with an element using SiC or GaN is called an SiC/GaN power semiconductor device) has drawn attention (for an example, see Patent Document 1).

Compared to elements in the related art that use Si, the aforementioned element can not only greatly reduce power loss but also operate at a higher voltage or current and at a high temperature equal to or higher than 200° C. Accordingly, the element is expected to be used in the field to which a Si power semiconductor device in the related art cannot be applied.

Such an element, which is represented by the element (semiconductor element) using SiC/GaN and can operate under harsh conditions, is required to exhibit a higher degree of heat resistance with respect to semiconductor encapsulating materials that are provided to semiconductor devices for protecting the element, compared to the elements in the related art.

In the Si power semiconductor device in the related art, from the viewpoint of adhesiveness, electric stability, and the like, a resin composition that contains a cured material of an epoxy-based resin composition as a main component is used as the semiconductor encapsulating material.

As an index indicating heat resistance of the cured material of a resin composition, a glass transition temperature (Tg) is generally used. This is because the resin composition (cured material) is in the form of rubber in a region having a temperature equal to or higher than Tg, and as a result, the strength or adhesive strength thereof decreases. Therefore, as methods of increasing Tg, techniques such as decreasing an epoxy group equivalent of an epoxy resin contained in a resin composition or decreasing a hydroxyl equivalent of a curing agent (phenol resin curing agent) so as to increase crosslink density, making a rigid structure that links these functional groups (an epoxy group and a hydroxyl group) with each other, and the like are adopted.

In addition to Tg, as an index indicating heat resistance of a resin composition, a weight reduction rate yielded by thermal decomposition is used. The weight of a resin composition is reduced by thermal decomposition caused in a portion in which an epoxy resin and a curing agent are linked to each other with weak bond energy. Accordingly, for a semiconductor encapsulating material having a high functional group density, it is disadvantageous to decrease the weight reduction rate. Therefore, the technique for decreasing the weight reduction rate and the technique for obtaining a high Tg as described above are used for opposed purposes.

Accordingly, in order to enhance heat resistance of a resin composition, it is desirable to design a resin structure, which is formed of an epoxy resin and a curing agent, and a functional group density under optimal conditions so as to obtain a high Tg. Moreover, it is desirable to form a resin composition designed to have a low weight reduction rate.

### RELATED DOCUMENT

### Patent Document

[Patent Document 1] Japanese Unexamined Patent Publication No. 2005-167035

### DISCLOSURE OF THE INVENTION

The present invention has been made based on the above circumstances, and provides a resin composition, which can realize both the increase of a glass transition temperature (Tg) and decrease of a weight reduction rate yielded by thermal decomposition, and an electronic device which exhibits excellent reliability at a high temperature by including a cured material obtained from the resin composition as a encapsulating material that encapsulates an electronic component such as a semiconductor element.

According to the present invention, a resin composition for encapsulation containing a phenol resin curing agent represented by Formula (1A), an epoxy resin represented by Formula (2A), and a release agent of which a 5% weight reduction temperature is equal to or higher than 240° C.

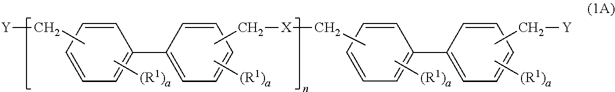

(In Formula (1A), each of two Ys independently represents a hydroxyphenyl group represented by Formula (1B) or Formula (1C); X represents a hydroxyphenylene group represented by Formula (1D) or Formula (1E), and n represents a number equal to or greater than 0. When n is equal to or greater than 2, each of two or more Xs may be independently the same as or different from each other; each of R¹s independently represents a hydrocarbon group having 1 to 5 carbon atoms; and a represents an integer of 0 to 4.)

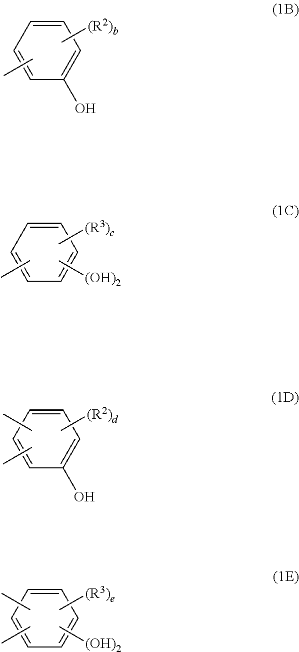

(In Formulae (1B) to (1E), each of R² and R³ independently represents a hydrocarbon group having 1 to 5 carbon atoms; b represents an integer of 0 to 4; c represents an integer of 0 to 3; d represents an integer of 0 to 3; and e represents an integer of 0 to 2.)

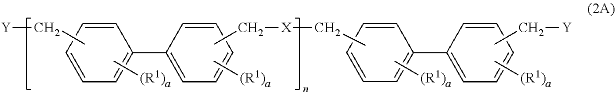

(In Formula (2A), each of two Ys independently represents a glycidylated phenyl group represented by Formula (2B) or Formula (2C); X represents a glycidylated phenylene group represented by Formula (2D) or Formula (2E); and n represents a number equal to or greater than 0. When n is equal to or greater than 2, each of two or more Xs may be independently the same as or different from each other; each of R¹s independently represents a hydrocarbon group having 1 to 5 carbon atoms; and a represents an integer of 0 to 4.)

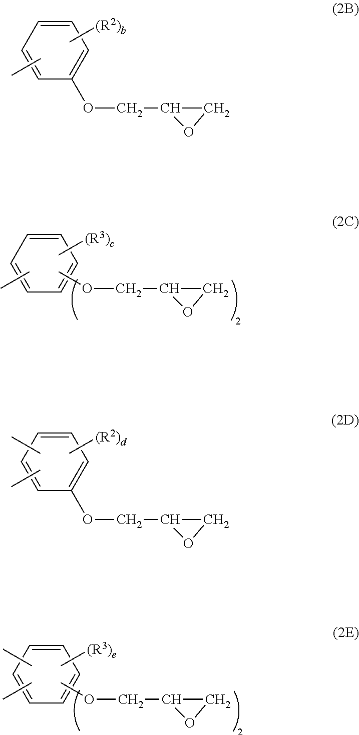

(In Formulae (2B) to (2E), each of R² and R³ independently represents a hydrocarbon group having 1 to 5 carbon atoms; b represents an integer of 0 to 4; c represents an integer of 0 to 3; d represents an integer of 0 to 3; and e represents an integer of 0 to 2.)

According to an embodiment of the present invention, in the resin composition for encapsulation, provided that a content of the phenol resin curing agent in the resin composition is A1 (% by mass), and a content of the epoxy resin is A2 (% by mass), a value of A1/(A1+A2) is equal to or greater than 0.2 and equal to or less than 0.9.

According to an embodiment of the present invention, in the resin composition for encapsulation, a hydroxyl equivalent of the phenol resin curing agent is equal to or greater than 90 g/eq and equal to or less than 190 g/eq.

According to an embodiment of the present invention, in the resin composition for encapsulation, an epoxy equivalent of the epoxy resin is equal to or greater than 160 g/eq and equal to or less than 290 g/eq.

According to an embodiment of the present invention, the resin composition for encapsulation further contains an inorganic filler.

According to an embodiment of the present invention, the resin composition for encapsulation further contains at least one kind of curing accelerator represented by Formula (6) to Formula (9).

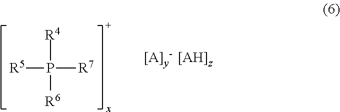

(In Formula (6), P represents a phosphorus atom; R⁴, R⁵, R⁶, and R⁷ represent aromatic groups or alkyl groups; A represents an anion of an aromatic organic acid having an aromatic ring to which at least one functional group selected from a hydroxyl group, a carboxyl group, and a thiol group is bonded; AH represents an aromatic organic acid having an aromatic ring to which at least one functional group selected from a hydroxyl group, a carboxyl group, and a thiol group is bonded; x and y are 1 to 3; z is 0 to 3; and x=y.)

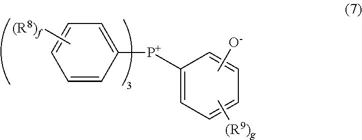

(In Formula (7), R⁸ represents an alkyl group having 1 to 3 carbon atoms; R⁹ represents a hydroxyl group; f is 0 to 5; and g is 0 to 3.)

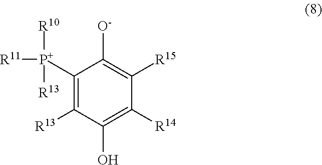

(In Formula (8), P represents a phosphorus atom; R¹⁰, R¹¹, and R¹² represent alkyl groups having 1 to 12 carbon atoms or aryl groups having 6 to 12 carbon atoms, and may be the same as or different from each other; R¹³, R¹⁴, and R¹⁵ represent hydrogen atoms or hydrocarbon groups having 1 to 12 carbon atoms, and may be the same as or different from each other; and R¹⁴ and R¹⁵ may form a cyclic group by being bonded to each other.)

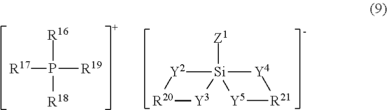

(In Formula (9), P represents a phosphorus atom; Si represents a silicon atom; each of R¹⁶, R¹⁷, Rⁿ, and R¹⁹ represents an organic group, which has an aromatic ring or a heterocycle, or an aliphatic group, and may be the same as or different from each other; R²⁰ is an organic group bonded to groups Y² and Y³; R²¹ is an organic group bonded to groups Y⁴ and Y⁵; Y² and Y³ represent groups formed when a proton-donating group releases protons; the groups Y² and Y³ in the same molecule form a chelate structure by being bonded to silicon atoms; Y⁴ and Y⁵ represent groups formed when a proton-donating group releases protons; the groups Y⁴ and Y⁵ in the same molecule form a chelate structure by being bonded to silicon atoms; R²⁰ and R²¹ may be the same as or different from each other; Y², Y³, Y⁴, and Y⁵ may be the same as or different from each other; and Z¹ is an organic group, which has an aromatic ring or a heterocycle, or an aliphatic group.)

According to an embodiment of the present invention, the resin composition for encapsulation further contains a coupling agent.

Moreover, according to the present invention, there is provided a resin composition for encapsulation containing an epoxy resin represented by Formula (2A) and a release agent of which a 5% weight reduction temperature is equal to or higher than 240° C.

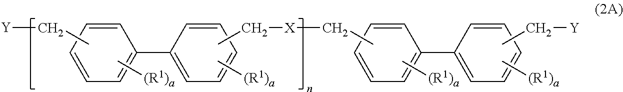

(In Formula (2A), each of two Ys independently represents a glycidylated phenyl group represented by Formula (2B) or Formula (2C); X represents a glycidylated phenylene group represented by Formula (2D) or Formula (2E) ; and n represents a number equal to or greater than 0. When n is equal to or greater than 2, each of two or more Xs may be independently the same as or different from each other; each of R¹ independently represents a hydrocarbon having 1 to 5 carbon atoms; and a represents an integer of 0 to 4.)

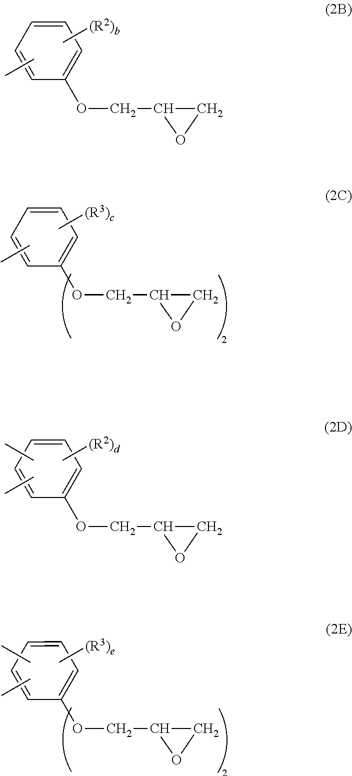

(In Formulae (2B) to (2E), each of R² and R³ independently represents a hydrocarbon group having 1 to 5 carbon atoms; b represents an integer of 0 to 4; c represents an integer of 0 to 3; d represents an integer of 0 to 3; and e represents an integer of 0 to 2.)

According to an embodiment of the present invention, a glass transition temperature (Tg) of the resin composition for encapsulation is equal to or higher than 200° C., and when the cured material is heated for 1,000 hours at 200° C. in the atmosphere, a weight reduction rate of the material becomes equal to or lower than 0.3%.

Moreover, according to the present invention, there is provided a resin composition for encapsulation containing a phenol resin curing agent, an epoxy resin, and a release agent of which a 5% weight reduction temperature is equal to or higher than 240° C., in which a glass transition temperature (Tg) of a cured material of the resin composition for encapsulation is equal to or higher than 200° C., and when the cured material is heated for 1,000 hours at 200° C. in the atmosphere, a weight reduction rate of the material becomes equal to or lower than 0.3%.

According to an embodiment of the present invention, in the resin composition for encapsulation, the phenol resin curing agent is represented by the Formula (1A), and the epoxy resin is represented by the Formula (2A).

Moreover, according to the present invention, there is provided an electronic device including an electronic component encapsulated with the resin composition.

The present invention provides a resin composition for encapsulation, which can realize both the increase of a glass transition temperature (Tg) and decrease of a weight reduction rate yielded by thermal decomposition, and an electronic device which exhibits superior reliability at a high temperature by including a cured material obtained from the resin composition as a encapsulating material that encapsulated a semiconductor element.

### BRIEF DESCRIPTION OF THE DRAWINGS

The aforementioned object, other objects, characteristics, and advantages are further clarified by preferred embodiments and accompanying drawings described below.

FIG. 1 is a vertical cross-sectional view showing an example case in which an electronic device using the resin composition of the present invention is applied to a semiconductor device.

### DESCRIPTION OF EMBODIMENTS

Hereinafter, the resin composition and the electronic device of the present invention will be described in detail based on embodiments.

First, the electronic device of the present invention will be described. In the following section, a case in which an electronic device using the resin composition of the present invention (electronic device of the present invention) is applied to a semiconductor device will be described. The semiconductor package described below is an example, and examples of preferred embodiments of a semiconductor chip include semiconductor chips using silicon carbide (SiC) and gallium nitride (GaN).

(Semiconductor Device)

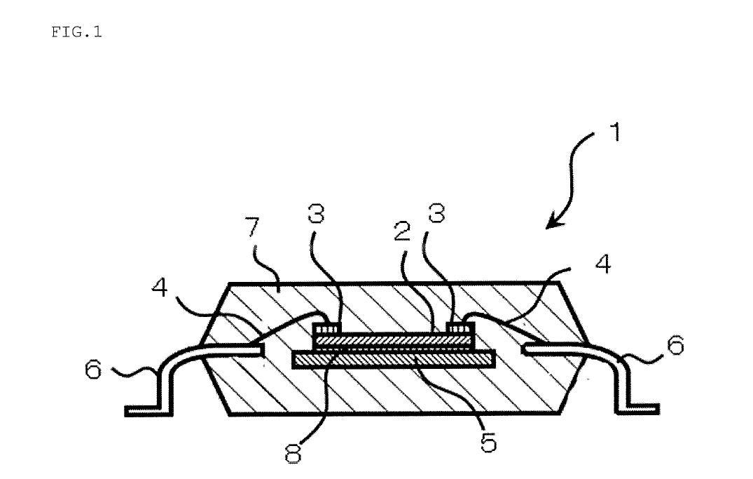

FIG. 1 is a vertical cross-sectional view showing an example case in which an electronic device using the resin composition of the present invention is applied to a semiconductor device. That is, in the following description, the upper side of FIG. 1 is described as “top”, and the lower side thereof is described as “bottom”.

A semiconductor device 1 shown in FIG. 1 is a Quad Flat Package (QFP)-type semiconductor package, and has a semiconductor chip (semiconductor element) 2, a die pad 5 that supports the semiconductor chip 2 through an adhesive layer 8, a lead 6 that is electrically connected to the semiconductor chip 2, and a mold portion (encapsulating portion) 7 that encapsulates the semiconductor chip 2.

Examples of the semiconductor chip 2 include semiconductor chips using silicon carbide (SiC) or gallium nitride (GaN).

The die pad 5 is constituted with a metallic substrate and functions as a support supporting the semiconductor chip 2.

The die pad 5 may be, for example, a metallic substrate that is constituted with Cu, Fe, Ni, or an alloy of these (for example, a Cu-based alloy or an iron.nickel-based alloy such as Fe-42Ni), a substrate obtained by plating the surface of the metallic substrate with silver or Ni—Pd, or a substrate in which a gold plating (gold flashing) layer for improving stability of the Pd layer is disposed on the Ni—Pd-plated surface.

When seen in a plan view, the shape of the die pad 5 corresponds to the shape of the semiconductor chip 2, and is, for example, a quadrangular shape such as a square or a rectangle. In the outer periphery of the die pad 5, plural leads 6 are disposed radially.

The end of the lead 6 that is at the side opposite to the die pad 5 protrudes (exposed) from the mold portion 7. The lead 6 is constituted with a conductive material. For example, the lead 6 can be constituted with the same material as being used for the die pad 5.

The surface of the lead 6 may be plated with tin, and by doing this, when the semiconductor device 1 is connected to a terminal of a mother board by solder, adhesiveness between the solder and the lead 6 can be improved.

The semiconductor chip 2 is bonded (fixed) to the die pad 5 through the adhesive layer 8. The adhesive layer 8 is not particularly limited, and is formed of, for example, an epoxy-based adhesive, an acrylic adhesive, a polyamide-based adhesive, and a cyanate-based adhesive.

The semiconductor chip 2 has an electrode pad 3. The electrode pad 3 and the lead 6 are electrically connected to each other through a wire 4. In this manner, the semiconductor chip 2 and each lead 6 are electrically connected to each other. The material constituting the wire 4 is not particularly limited, and examples thereof include an Au wire, an Al wire, a Cu wire, and an Ag wire.

The die pad 5, the respective members disposed on the top surface of the die pad 5, and the internal part of the lead 6 are encapsulated with the mold portion 7. Therefore, the external end of the lead 6 protrudes from the mold portion 7.

The mold portion 7 is constituted with a cured material of the resin composition of the present invention. For example, the mold portion 7 is formed in a manner in which the respective members described above are encapsulated with the resin composition of the present invention by using a molding method such as transfer molding, and then the resin composition is completely cured for about 10 minutes to 10 hours at a temperature of about 80° C. to 200° C.

If silicon carbide (SiC) or gallium nitride (GaN) is used for the semiconductor chip 2, as described in the section of “BACKGROUND ART”, the mold portion 7 is required to exhibit adhesiveness, electric stability, flame retardancy, heat resistance (particularly, regarding the heat resistance, compatibility between increase of Tg and decrease of weight reduction), and excellent reliability at a high temperature.

Hereinafter, the resin composition will be described.

(Resin Composition)

The resin composition of the present invention contains a phenol resin curing agent represented by Formula (1A), an epoxy resin represented by Formula (2A), and a release agent of which a 5% weight reduction temperature is equal to or higher than 240° C.

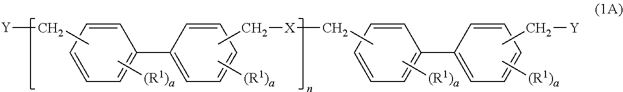

(In Formula (1A), each of two Ys independently represents a hydroxyphenyl group represented by Formula (1B) or Formula (1C); X represents a hydroxyphenylene group represented by Formula (1D) or Formula (1E); and n represents a number equal to or greater than 0. When n is equal to or greater than 2, each of two or more Xs may be independently the same as or different from each other; each of R¹s independently represents a hydrocarbon group having 1 to 5 carbon atoms; and a represents an integer of 0 to 4.)

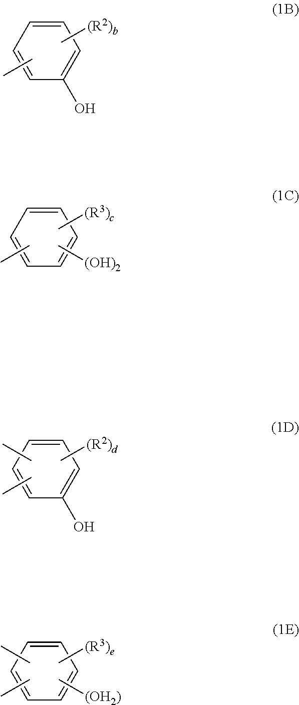

(In Formulae (1B) to (1E); each of R² and R³ independently represents a hydrocarbon group having 1 to 5 carbon atoms; b represents an integer of 0 to 4; c represents an integer of 0 to 3; d represents an integer of 0 to 3; and e represents an integer of 0 to 2.)

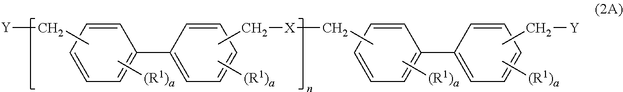

(In Formula (2A), each of two Ys independently represents a glycidylated phenyl group represented by Formula (2B) or Formula (2C); X represents a glycidylated phenylene group represented by Formula (2D) or Formula (2E); and n represents a number equal to or greater than 0. When n is equal to or greater than 2, each of two or more Xs may be independently the same as or different from each other; each of Fes independently represents a hydrocarbon group having 1 to 5 carbon atoms; and a represents an integer of 0 to 4.)

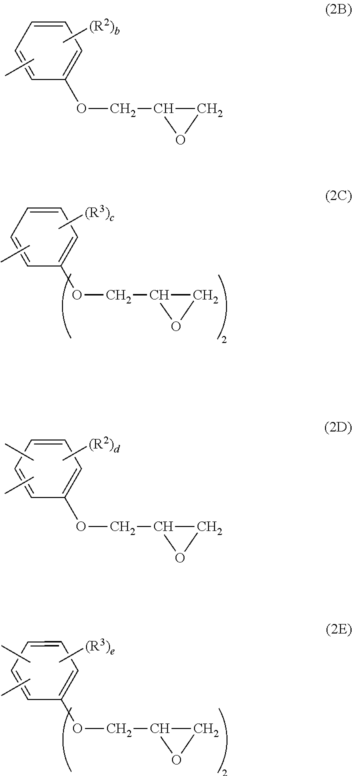

(In Formulae (2B) to (2E), each of R² and R³ independently represents a hydrocarbon group having 1 to 5 carbon atoms; b represents an integer of 0 to 4; c represents an integer of 0 to 3; d represents an integer of 0 to 3; and e represents an integer of 0 to 2.)

Hereinafter, the respective components contained in the resin composition will be described.

(Phenol Resin Curing Agent)

The phenol resin curing agent used for the resin composition of the present invention is a polymer represented by Formula (1A). In the present specification, the “polymer” includes compounds represented by Formula (1A) in which n=0.

The phenol resin curing agent functions to cure the resin composition by causing the epoxy resin molecules to be crosslinked with each other through the curing agent.

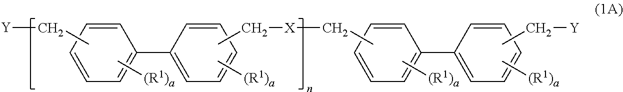

(In Formula (1A), each of two Ys independently represents a hydroxyphenyl group represented by Formula (1B) or Formula (10); X represents a hydroxyphenylene group represented by Formula (1D) or Formula (1E); and n represents a number equal to or greater than 0. When n is equal to or greater than 2, each of two or more Xs may be independently the same as or different from each other; each of R¹s independently represents a hydrocarbon group having 1 to 5 carbon atoms; and a represents an integer of 0 to 4.)

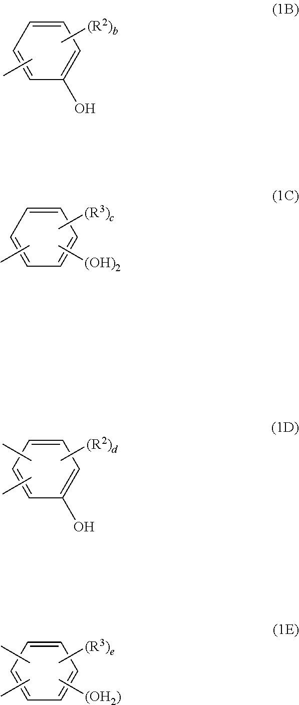

(In Formulae (1B) to (1E), each of R² and R³ independently represents a hydrocarbon group having 1 to 5 carbon atoms; b represents an integer of 0 to 4; c represents an integer of 0 to 3; d represents an integer of 0 to 3; and e represents an integer of 0 to 2.)

In the phenol resin curing agent represented by Formula (1A), n is an average and is preferably 0 to 6, more preferably 0 to 3, and even more preferably 0 to 1. A number average molecular weight of the phenol resin curing agent represented by Formula (1A) is preferably equal to or more than 390 and equal to or less than 1,000, more preferably equal to or more than 400 and equal to or less than 600, even more preferably equal to or more than 400 and equal to or less than 550, and particularly preferably equal to or more than 400 and equal to or less than 500. The phenol resin curing agent has an aromatic ring substituted with plural hydroxyl groups. Accordingly, in the phenol resin curing agent, intermolecular interaction derived from hydrogen bonds is strong. Moreover, regarding moldability, particularly, filling properties obtained during continuous molding, the phenol resin curing agent sometimes shows unique behavior different from the behavior of the resin in the related art that results from the concept of fluidity or curability that is defined in the related art. If the phenol resin curing agent of which the number average molecular weight is within the above range is used, a resin composition having excellent curability and continuous moldability is obtained, and the cured material thereof has a high glass transition temperature and a low weight reduction rate. The value of n can be calculated from the number average molecular weight, X and Y described above, and the structure of a biphenyl skeleton and a ratio of components thereof.

In Formulae (1A) to (1E), each of R¹, R², and R³ independently represents a hydrocarbon group having 1 to 5 carbon atoms. If the number of carbon atoms contained in R¹, R², and R³ is equal to or less than 5, reactivity of the obtained resin composition is lowered, whereby deterioration of moldability can be reliably prevented.

Specifically, examples of the substituents R¹, R², and R³ include alkyl groups such as a methyl group, an ethyl group, a propyl group, an n-butyl group, an isobutyl group, a t-butyl group, an n-pentyl group, a 2-methylbutyl group, a 3-methylbutyl group, and a t-pentyl group, and among these, a methyl group is preferable. If a methyl group is used as the substituent, balance between curability and hydrophobicity of the resin composition can be particularly excellent.

a represents the number of substituent R¹ bonded to the same benzene ring in Formula (1A). Each a is independently an integer of 0 to 4. b and d represent the number of substituent R² bonded to the same benzene ring in Formulae (1B) and (1D). Each b is independently an integer of 0 to 4, and each d is independently an integer of 0 to 3. c and e represent the number of substituent R³ bonded to the same benzene ring in Formulae (1C) and (1E). Each c is independently 0 to 3, and each e is independently an integer of 0 to 2. a is preferably an integer of 0 to 2, and b, c, d, and e are preferably an integer of 0 or 1.

In the present invention, the phenol resin curing agent represented by Formula (1A) contains a monovalent hydroxyphenyl group represented by Formula (1B) (hereinafter, the monovalent hydroxyphenyl group means a hydroxyphenyl group having one hydroxyl group) and a monovalent hydroxyphenylene group represented by Formula (1D) (hereinafter, the monovalent hydroxyphenylene group means a hydroxyphenylene group having one hydroxyl group), and further contains a divalent hydroxyphenyl group represented by Formula (1C) (hereinafter, the divalent hydroxyphenyl group means a hydroxyphenyl group having two hydroxyl groups) and a divalent hydroxyphenylene group represented by Formula (1E) (hereinafter, the divalent hydroxyphenylene group means a hydroxyphenylene group having two hydroxyl groups). If the phenol resin curing agent that contains monovalent hydroxyphenyl group represented by Formula (1B) and the monovalent hydroxyphenylene group represented by Formula (1D) is used, the obtained resin composition exhibits excellent flame retardancy, a low water absorption rate, and soldering resistance.

In the phenol resin curing agent containing the divalent hydroxyphenyl group represented by Formula (1C) and the divalent hydroxyphenylene group represented by Formula (1E), density of phenolic hydroxyl groups is high. Accordingly, the cured material of the obtained resin composition has a high glass transition temperature (Tg). Generally, in the polymer having phenolic hydroxyl groups, such as the phenol resin curing agent represented by Formula (1A), the higher the density of the phenolic hydroxyl groups is, the higher the weight reduction rate thereof becomes. However, in a crosslinked substance consisting of the phenol resin curing agent represented by Formula (1A) and an epoxy resin, increase of the weight reduction rate resulting from increase of Tg is suppressed. The following is considered to be the reason, though it is not a definite reason. That is, the portion of methylene group that connects the biphenyl skeleton to the divalent phenol in the crosslinked substance may be protected by steric bulkiness, and accordingly, the resin composition may undergo thermal decomposition relatively to a smaller extent.

In the phenol resin curing agent represented by Formula (1A), provided that the sum of the number of the hydroxyphenyl group represented by Formula (1B) and the number of the hydroxyphenylene group represented by Formula (1D) is k, the average of k is k0, the sum of the number of hydroxyphenyl group represented by Formula (1C) and the number of the hydroxyphenylene group represented by Formula (1E) is m, and the average of m is m0, the value of k0/m0 is preferably 0/100 to 82/18, more preferably 20/80 to 80/20, and even more preferably 25/75 to 75/25. If the value of k0/m0 is within the above range, a resin composition in which the fluidity, soldering resistance, flame retardancy, continuous moldability, and heat resistance are excellently balanced can be obtained economically.

The value of k0 and m0 can be obtained by arithmetical calculation by regarding a relative intensity ratio measured by Field Desorption Mass Spectrometry (FD-MS) as a mass ratio. Alternatively, the value of k0 and m0 can be obtained by H-NMR spectroscopy or C-NMR spectroscopy.

(Method for Producing Phenol Resin Curing Agent)

The phenol resin curing agent represented by Formula (1A) can be produced by the following method.

The phenol resin curing agent represented by Formula (1A) can be produced by, for example, causing a reaction among a biphenylene compound represented by Formula (3), a monovalent phenol compound represented by Formula (4), and a divalent phenol compound represented by Formula (5) in the presence of an acidic catalyst.

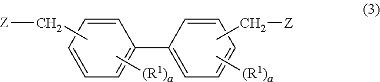

(In Formula (3), Z represents a hydroxyl group, a halogen atom, or an alkoxy group having 1 to 6 carbon atoms; R¹ represents a hydrocarbon group having 1 to 5 carbon atoms; and a represents an integer of 0 to 4.)

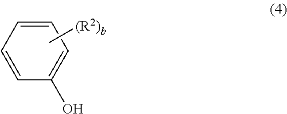

(In Formula (4), R² represents a hydrocarbon group having 1 to 5 carbon atoms; and b represents an integer of 0 to 4.)

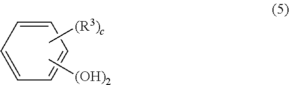

(In Formula (5), R³ represents a hydrocarbon having 1 to 5 carbon atoms; and c represents an integer of 0 to 3.)

Examples of the halogen atom represented by Z of the compound represented by Formula (3) include a fluorine atom, a chlorine atom, a bromine atom, an iodine atom, and the like. Examples of the alkoxy group having 1 to 6 carbon atoms include a methoxy group, an ethoxy group, a propoxy group, an n-butoxy group, an isobutoxy group, a t-butoxy group, an n-pentoxy group, a 2-methylbutoxy group, a 3-methylbutoxy group, a t-pentoxy group, an n-hextoxy group, a 1-methylpentoxy group, a 2-methylpentoxy group, a 3-methylpentoxy group, a 4-methylpentoxy group, a 2,2-dimetylbutoxy group, a 2,3-dimethylbutoxy group, a 2,4-dimethylbutoxy group, a 3,3-dimethylbutoxy group, a 3,4-dimethylbutoxy group, a 4,4-dimethylbutoxy group, a 2-ethylbutoxy group, a 1-ethylbutoxy group, and the like. Examples of the hydrocarbon group having 1 to 5 carbon atoms that is represented by R¹ include alkyl groups such as a methyl group, an ethyl group, a propyl group, a n-butyl group, an isobutyl group, a t-butyl group, a n-pentyl group, a 2-methylbutyl group, a 3-methylbutyl group, and a t-pentyl group.

Specific examples of the compound represented by Formula (3) include 4,4′-bischloromethylbiphenyl, 4,4′-bisbromomethylbiphenyl, 4,4′-bisiodomethylbiphenyl, 4,4′-bishydroxymethylbiphenyl, 4,4′-bismethoxymethylbiphenyl, and the like. One kind of these compounds can be used singly, or two or more kinds thereof can be used in combination. Among the compounds, it is preferable to use 4,4′-bismethoxymethylbiphenyl or 4,4′-bischloromethylbiphenyl. 4,4′-Bismethoxymethylbiphenyl is preferably used, since this compound can be synthesized at a relatively low temperature and makes it easy to distill away or handle byproducts of reaction. 4,4′-Bischloromethylbiphenyl is preferably used, since this compound makes it possible to use a hydrogen halide, which is generated by a trace of moisture, as an acid catalyst.

Examples of the monovalent phenol compound represented by Formula (4) include phenol, o-cresol, p-cresol, m-cresol, phenylphenol, ethylphenol, n-propylphenol, isopropylphenol, t-butylphenol, xylenol, methylpropylphenol, methylbutylphenol, dipropylphenol, dibutylphenol, nonylphenol, mesitol, 2,3,5-trimethylphenol, 2,3,6-trimethylphenol, and the like. One kind of these compounds may be used singly, or two or more kinds thereof may be used concurrently. Among these, phenol and o-cresol are preferable. Particularly, phenol is more preferably used since it exhibits excellent reactivity with respect to an epoxy resin.

Examples of the divalent phenol compound represented by Formula (5) include resorcinol, catechol, hydroquinone, and the like. One kind of these compounds may be used singly, or two or more kinds thereof may be used concurrently. Among these, resorcinol and hydroquinone are preferably used from the viewpoint of the reactivity of the resin composition. Particularly, resorcinol is more preferably used since this compound makes it possible to synthesize the phenol resin curing agent at a relatively low temperature.

The acidic catalyst is not particularly limited, and examples thereof include formic acid, oxalic acid, p-toluenesulfonic acid, hydrochloric acid, sulfuric acid, phosphoric acid, acetic acid, trifluoromethanesulfonic acid, Lewis acid, and the like. One kind of these catalysts can be used singly, or two or more kinds thereof can be used in combination.

When the group Z in the compound represented by Formula (3) is a halogen atom, a hydrogen halide produced as a byproduct by the reaction acts as an acidic catalyst. Therefore, an acidic catalyst does not need to be added to the reaction system, whereby the reaction can be rapidly started by adding a small amount of water.

In the aforementioned method for producing the phenol resin curing agent, the reaction conditions can be adjusted such that a number average molecular weight of the obtained phenol resin curing agent becomes preferably equal to or more than 390 and equal to or less than 1,000, more preferably equal to or more than 400 and equal to or less than 600, even more preferably equal to or more than 400 and equal to or less than 550, and particularly preferably equal to or more than 400 and equal to or less than 500. For example, a total of 1 mol of the monovalent phenol compound and the divalent phenol compound are reacted with 0.01 moles to 0.8 mol of a biphenylene compound and optionally with 0.01 moles to 0.05 mol of an acidic catalyst. Thereafter, while the generated gas and moisture are being discharged out of the system by using a nitrogen flow, the reactants are reacted at 80° C. to 170° C. for 1 to 20 hours. Subsequently, unreacted monomers (for example, benzyl compounds or dihydroxynaphthalene compounds) remaining after the reaction ends, byproducts of the reaction (for example, a hydrogen halide and methanol), and the catalyst are distilled away by methods such as distillation under reduced pressure and steam distillation, whereby a phenol resin curing agent having a desired number average molecular weight can be obtained.

In the aforementioned method for producing the phenol resin curing agent, the reaction conditions can be adjusted, such that a mixing ratio (k0/m0) between the monovalent phenol compound of Formulae (1B) and (1D) and the divalent phenol compound of Formulae (10) and (1E) contained in the obtained phenol resin curing agent becomes preferably 0/100 to 82/18, more preferably 20/80 to 80/20, and even more preferably 25/75 to 75/25. For example, based on a total of 100 mol % of the monovalent phenol compound and the divalent phenol compound, the monovalent phenol compound can be reacted preferably in an amount of 15 mol % to 85 mol %, more preferably in an amount of 20 mol % to 80 mol %, and even more preferably in an amount of 20 mol % to 75 mol %. If the proportion of the monovalent phenol compound mixed in is equal to or higher than the above lower limit, increase in the raw material cost can be suppressed, and a resin composition exhibiting excellent fluidity can be obtained. If the proportion of the monovalent phenol compound mixed in is equal to or lower than the above upper limit, the obtained resin composition exhibits excellent fluidity, soldering resistance, and flame retardancy and shows sufficient toughness at a molding temperature, and accordingly, moldability thereof can become excellent. If the mixing ratio between two kinds of the phenol compounds is within the range described above, it is possible to economically obtain a resin composition in which fluidity, soldering resistance, flame retardancy, heat resistance, and moldability, particularly, continuous moldability are excellently balanced.

The number average molecular weight, hydroxyl equivalent, and value of k0/m0 of the phenol resin curing agent represented by Formula (1A) can be adjusted using a phenol resin synthesis method known to those skilled in the art. For example, the value of k0/m0 of the phenol resin curing agent can be adjusted by the mixing ratio between the monovalent phenol compound and the divalent phenol compound used for the synthesis. More specifically, by a method in which the amount of the biphenylene compound with respect to the total amount of the monovalent phenol compound and the divalent phenol compound used for synthesizing the phenol resin curing agent is set to be approximately 1:1 in terms of a molar ratio, a phenol resin curing agent having a high molecular weight and high viscosity can be obtained. Meanwhile, by methods such as a method of decreasing the molar ratio of the biphenylene compound to the total amount of the monovalent phenol compound and the divalent phenol compound used for synthesizing the phenol resin curing agent, a method of decreasing the amount of the acid catalyst to be mixed in, a method of rapidly discharging hydrogen halide gas out of the system by using a nitrogen gas flow if such gas is generated, and a method of decreasing the reaction temperature, the amount of generated high-molecular weight components is reduced, whereby a phenol resin curing agent having a number average molecular weight that is within the preferable range described above can be obtained. In this case, the way the reaction proceeds can be checked, by observing the state of gas of a hydrogen halide or an alcohol that is produced as a byproduct by the reaction among the biphenylene compound of Formula (3), the monovalent phenol compound of Formula (4), and the divalent phenol compound of Formula (5), or by measuring the molecular weight of the products produced during the reaction by means of gel permeation chromatography.

The resin composition may contain other curing agents, within a range in which the effect obtained by the use of the phenol resin curing agent represented by Formula (1A) is not diminished. The amount of the phenol resin curing agent represented by Formula (1A) that is contained in the resin composition is preferably equal to or more than 50% by mass of all curing agents. The curing agent that can be concurrently used is not particularly limited, and examples thereof include polyaddition-type curing agents, catalyst-type curing agents, condensation-type curing agents, and the like. One kind of these curing agents can be used singly, or two or more kinds thereof can be used in combination.

Examples of the polyaddition-type curing agents include aliphatic polyamine such as diethylenetriamine, triethylenetetramine, and m-xylenediamine; aromatic polyamine such as diaminodiphenylmethane, m-phenylenediamine, and diaminodiphenylsulfone; polyamine compounds such as dicyan diamide and organic acid dihydrazide; alicyclic acid anhydrides such as hexahydrophthalic anhydride and methyltetrahydrophthalic anhydride; acid anhydrides including aromatic acid anhydrides such as trimellitic anhydride, pyromellitic anhydride, and benzophenone tetracarboxylic acid; compounds that are known to those skilled in the art as phenol resin curing agents in the field of semiconductor encapsulating material, such as novolac-type phenol resins, and phenol polymers represented by polyvinyl phenol; polymercaptan compounds such as polysulfide, thioester, and thioether; isocyanate compounds such as isocyanate prepolymers and blocked isocyanate; organic acids such as carboxylic acid-containing polyester resins; and the like.

Examples of the catalyst-type curing agents include tertiary amine compounds such as benzyldimethylamine, and 2,4,6-trisdimethylaminomethylphenol; imidazole compounds such as 2-methylimidazole and 2-ethyl-4-methylimidazole; Lewis acids such as a BF₃ complex; and the like.

Examples of the condensation-type curing agents include phenol resin curing agents such as resol-type phenol resins; urea resins such as methylol group-containing urea resins; melamine resins such as methylol group-containing melamine resins; and the like.

Among these, in view of balance among flame retardancy, moisture resistance, electric characteristics, curability, storage stability, and the like, phenol resin curing agents are preferable.

Examples of other phenol resin curing agents include novolac-type resins such as phenol novolac resins, cresol novolac resins, and naphthol novolac resins; polyfunctional phenol resins such as triphenolmethane-type phenol resins; modified phenol resins such as terpene-modified phenol resins and dicyclopentadiene-modified phenol resins; aralkyl-type resins such as phenol aralkyl resins having a phenylene skeleton and/or a biphenylene skeleton and naphthol aralkyl resins having a phenylene and/or biphenylene skeleton; bisphenol compounds such as bisphenol A and bisphenol F; and the like. One kind of these compounds may be used singly, or two or more kinds thereof may be used concurrently. Among these, in view of curability, phenol resin curing agents having a hydroxyl equivalent equal to or more than 90 g/eq and equal to or less than 250 g/eq are preferable.

The amount of all curing agents including the phenol resin curing agent that are mixed into the resin composition of the present invention is preferably equal to or more than 1% by mass and equal to or less than 20% by mass, more preferably equal to or more than 2% by mass and equal to or less than 15% by mass, and even more preferably equal to or more than 3% by mass and equal to or less than 10% by mass. If the amount is within the above range, a resin composition in which curability, heat resistance, and soldering resistance are excellently balanced is obtained.

(Epoxy Resin)

The epoxy resin used for the resin composition of the present invention is a polymer represented by Formula (2A). In the present specification, the “polymer” include compounds represented by Formula (2A) in which n=0.

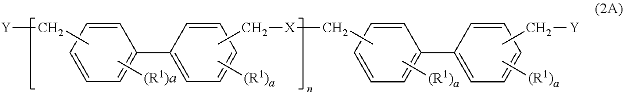

(In in Formula (2A), each of two Ys independently represents a glycidylated phenyl group represented by Formula (2B) or Formula (2C); X represents a glycidylated phenylene group represented by Formula (2D) or Formula (2E); and n represents a number equal to or greater than 0. When n is equal to or greater than 2, each of two or more Xs may be independently the same as or different from each other; each of R¹s independently represents a hydrocarbon group having 1 to 5 carbon atoms; and a represents an integer of 0 to 4.)

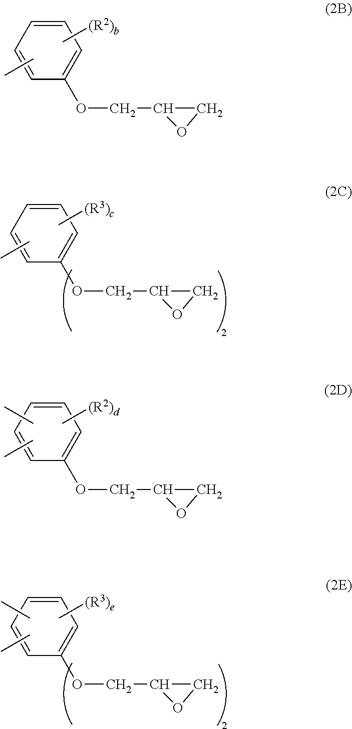

(In Formulae (2B) to (2E), each of R² and R³ independently represents a hydrocarbon group having 1 to 5 carbon atoms; b represents an integer of 0 to 4; c represents an integer of 0 to 3; d represents an integer of 0 to 3; and e represents an integer of 0 to 2.)

In the epoxy resin represented by Formula (2A), n is an average which is preferably 0 to 6, more preferably 0 to 3, and even more preferably 0 to 1. A number average molecular weight of the epoxy resin represented by Formula (2A) is preferably equal to or more than 450 and equal to or less than 2,000, more preferably equal to or more than 500 and equal to or less than 1,000, even more preferably equal to or more than 500 and equal to or less than 800, and most preferably equal to or more than 500 and equal to or less than 700. In the process of curing, such an epoxy resin is greatly influenced by the interaction between hydrogen bonds derived from the phenol resin curing agent containing an aromatic ring having plural hydroxyl groups. Therefore, regarding moldability, particularly, filling properties obtained during continuous molding, the epoxy resin sometimes shows unique behavior different from the behavior of the resin in the related art that results from the concept of fluidity or curability that is defined in the related art. If the epoxy resin having a number average molecular weight within the above range is used, a resin composition exhibiting excellent curability and continuous moldability is obtained, and the cured material thereof has a high glass transition temperature and a low weight reduction rate. n can be calculated from the number average molecular weight, X and Y described above, and the structure of a biphenyl skeleton and a ratio of components thereof.

In Formula (2A), each R¹ independently represents a hydrocarbon group having 1 to 5 carbon atoms. In Formulae (2B) to (2E), each of R² and R³ independently represents a hydrocarbon group having 1 to 5 carbon atoms. If the number of carbon atoms contained in R¹, R², and R³ is equal to or less than 5, reactivity of the obtained resin composition is lowered, whereby deterioration of moldability can be reliably prevented.

Specifically, examples of the substituents R¹, R², and R³ include alkyl groups such as a methyl group, an ethyl group, a propyl group, an n-butyl group, an isobutyl group, a t-butyl group, an n-pentyl group, a 2-methylbutyl group, a 3-methylbutyl group, and a t-pentyl group, and among these, a methyl group is preferable. If a methyl group is used as the substituent, balance between curability and hydrophobicity of the resin composition can be particularly excellent.

In Formula (2A), a represents the number of substituent R¹ bonded to the same benzene ring. Each a is independently an integer of 0 to 4. b and d in Formulae (2B) and (2D) represent the number of substituent R² bonded to the same benzene ring. Each b is independently an integer of 0 to 4, and each d is independently an integer of 0 to 3. c and e in Formulae (2C) and (2E) represent the number of substituent R³ bonded to the same benzene ring. Each c is independently 0 to 3, and each e is independently an integer of 0 to 2. b, c, d, and e are preferably an integer of 0 or 1.

According to an embodiment of the present invention, the epoxy resin represented by Formula (2A) contains a glycidylated phenyl group that is represented by Formula (2B) and has one glycidyl ether group, a glycidylated phenylene group that is represented by Formula (2D) and has one glycidyl ether group, a glycidylated phenyl group that is represented by Formula (2C) and has two glycidyl ether groups, and a glycidylated phenylene group that is represented by Formula (2E) and has two glycidyl ether groups.

If the epoxy resin, which contains the glycidylated phenyl group that is represented by Formula (2B) and has one glycidyl ether group and the glycidylated phenylene group that is represented by Formula (2D) and has one glycidyl ether group, is used, the obtained resin composition exhibits excellent flame retardancy, a low water absorption rate, and soldering resistance.

In the epoxy resin, which contains the glycidylated phenyl group that is represented by Formula (2C) and has two glycidyl ether groups and the glycidylated phenylene group that is represented by Formula (2E) and has two glycidyl ether groups, density of the glycidyl ether groups is high. Therefore, the cured material of the obtained resin composition has a high glass transition temperature (Tg). Generally, in the epoxy resin represented by Formula (2A), the higher the density of the glycidyl ether groups is, the higher the weight reduction rate becomes. However, in a crosslinked substance consisting of the epoxy resin represented by Formula (2A) and the aforementioned phenol resin curing agent, increase of the weight reduction rate resulting from increase of Tg is suppressed. The following is considered to be the reason, though it is not a definite reason. That is, the portion of methylene group that connects the biphenyl skeleton to the monovalent or divalent phenol in the crosslinked substance may be protected by steric bulkiness, and accordingly, the resin composition may undergo thermal decomposition relatively to a smaller extent.

(Method for Producing Epoxy Resin)

The epoxy resin represented by Formula (2A) can be produced by the following method.

The epoxy resin represented by Formula (2A) can be produced by for example, causing a reaction between the phenol resin curing agent represented by Formula (1A) and epichlorohydrin so as to substitute hydroxyl groups of the phenol resin curing agent with glycidyl ether groups. At this time, as the phenol resin curing agent represented by Formula (1A) that is used as a raw material, compounds that are in the form of preferable curing agents can be selected and used.

More specifically, the phenol resin curing agent represented by Formula (1A) is mixed with epichlorohydrin in an excess amount. Thereafter, in the presence of an alkali metal hydroxide such as sodium hydroxide and potassium hydroxide, the mixture is reacted preferably at 50° C. to 150° C. and more preferably at 60° C. to 120° C., preferably for about 1 to 10 hours. Subsequently, after the reaction ends, the epichlorohydrin in an excess amount is removed by distillation, the residues are dissolved in an organic solvent such as methyl isobutyl ketone, filtered, and washed with water to remove inorganic salts, and then the organic solvent is distilled away, thereby obtaining the epoxy resin.

The amount of epichlorohydrin added is preferably set such that the amount preferably becomes about 2-fold moles to 15-fold moles and more preferably becomes about 2-fold moles to 10-fold moles with respect to the hydroxyl equivalent of the phenol resin curing agent as a raw material. The amount of the alkali metal hydroxide added is set such that the amount preferably becomes about 0.8-fold moles to 1.2-fold moles and more preferably becomes about 0.9-fold moles to 1.1-fold moles with respect to the hydroxyl equivalent of the phenol resin curing agent.

The resin composition may contain other epoxy resins within a range in which the effect obtained by the use of the epoxy resin represented by Formula (2A) is not diminished. The amount of the epoxy resin represented by Formula (2A) that is contained in the resin composition is preferably equal to or more than 50% by mass of all epoxy resins.

Examples of other epoxy resins include crystalline epoxy resins such as biphenyl-type epoxy resins, bisphenol-type epoxy resins, stilbene-type epoxy resins, sulfide-type epoxy resins, and dihydroxyanthracene-type epoxy resins; novolac-type epoxy resins such as methoxynaphthalene skeleton-containing novolac-type epoxy resins, phenol novolac-type epoxy resins, and cresol novolac-type epoxy resins; phenol-modified aromatic hydrocarbon-formaldehyde resin-type epoxy resins that are obtained by modifying a resin, which is obtained by causing condensation between aromatic hydrocarbon and formaldehyde, with phenol and epoxylating the resin; polyfunctional epoxy resins such as triphenolmethane-type epoxy resins, alkyl-modified triphenolmethane-type epoxy resins, and tetrakishydroxyphenylethane-type epoxy resins; aralkyl-type epoxy resins such as phenol aralkyl-type epoxy resins having a phenylene skeleton and phenol aralkyl-type epoxy resins having a biphenylene skeleton; naphthol-type epoxy resins such as dihydroxynaphthalene-type epoxy resins and epoxy resins that are obtained by glycidyl etherifying a dimer of dihydroxynaphthalene; triazine core-containing epoxy resins such as triglycidyl isocyanurate and monoallyl diglycidyl isocyanurate; bridged cyclic hydrocarbon compound-modified phenol-type epoxy resins such as dicyclopentadiene-modified phenol-type epoxy resins; and phenolphthalein-type epoxy resins obtained by causing a reaction between phenolphthalein and epichlorohydrin. One kind of these resins can be used singly, or two or more kinds thereof can be used in combination.

Among these epoxy resins, in view of excellent fluidity, the crystalline epoxy resins are preferable. The polyfunctional epoxy resins are preferable, since these exhibit excellent heat resistance and contaminate a mold to a small extent during continuous molding. The phenolphthalein-type epoxy resins are preferable, since these exhibit an excellent balance between flame retardancy and soldering resistance, even when the content of an inorganic filler which will be described later is small. The epoxy resins like aralkyl-type epoxy resins such as phenol aralkyl-type epoxy resins having a phenylene skeleton, the phenol aralkyl-type epoxy resins having a biphenylene skeleton, and the phenol-modified aromatic hydrocarbon-formaldehyde resin-type epoxy resins are preferable, since these exhibit excellent soldering resistance. The epoxy resins having a naphthalene skeleton in a molecule, such as the naphthol-type epoxy resins and the methoxynaphthalene skeleton-containing novolac-type epoxy resins, are preferable, since these exhibit excellent balance between flame retardancy and heat resistance.

From the viewpoint of reliable moisture resistance, it is preferable for the resin composition not to contain Na ions or Cl ions that are ionic impurities as much as possible. Moreover, from the viewpoint of curability of the resin composition, an epoxy equivalent of the epoxy resin is preferably equal to or more than 100 g/eq and equal to or less than 500 g/eq.

The total amount of the epoxy resin in the resin composition is preferably equal to or more than 1% by mass and equal to or less than 20% by mass, more preferably equal to or more than 2% by mass and equal to or less than 15% by mass, and even more preferably equal to or more than 3% by mass and equal to or less than 10% by mass, with respect to the entire resin composition. If the epoxy resin is used within the above range, excellent curability, heat resistance, and soldering resistance are well balanced in the obtained resin composition.

As described above, in an embodiment of the present invention, the resin composition contains, as main components, a polymer represented by Formula (1A) as a phenol resin curing agent and a polymer represented by Formula (2A) as an epoxy resin. The polymer represented by Formula (1A) contains at least one of the divalent hydroxyphenyl group represented by Formula (10) and the divalent hydroxyphenylene group represented by Formula (1E). Moreover, the polymer represented by Formula (2A) contains at least one of the glycidylated phenyl groups that is represented by Formula (2C) and has two glycidyl ether groups and the glycidylated phenylene group that is represented by Formula (2E) and has two glycidyl ether groups.

That is, in the polymer represented by Formula (1A), two hydroxyl groups are introduced into the phenyl groups constituting the main skeleton thereof. Moreover, in the polymer represented by Formula (2A), two glycidyl ether groups are introduced into the phenyl groups constituting the main skeleton thereof. Due to the above constitution, density of hydroxyl groups can be improved in the polymer represented by Formula (1A), and density of epoxy groups can be improved in the polymer represented by Formula (2A).

As described above, in both the polymer represented by Formula (1A) as the phenol resin curing agent and the polymer represented by Formula (2A) as the epoxy resin, density of functional groups is improved. Accordingly, crosslink density of the cured material, which is formed by crosslinking epoxy resin molecules through the phenol resin curing agent, is improved. As a result, a glass transition temperature (Tg) of the cured material increases.

The polymer represented by Formula (1A) and the polymer represented by Formula (2A) can have the same main skeleton. That is, in the polymer represented by Formula (1A), hydroxyl groups are introduced into phenyl groups constituting the main skeleton thereof, and in the polymer represented by Formula (2A), glycidyl ether groups are introduced into the phenyl groups constituting the main skeleton thereof; however, except for the above point, these polymers can be embodied such that they have the same structural unit. In other words, these polymers contain a structural unit having the same main skeleton.

Generally, when the density of functional groups is increased to increase a glass transition temperature (Tg) of a cured material of a resin composition, as a counter reaction with respect to the above, crosslinking points (linkage portions) formed by a reaction between an epoxy group (glycidyl ether group) and a hydroxyl group undergo thermal decomposition, whereby a weight reduction rate increases. However, in the aforementioned embodiment of the present invention, even when the density of functional groups is increased, the weight reduction resulting from thermal decomposition of the crosslinking points can be prevented or suppressed. Presumably, this is because the polymer represented by Formula (1A) and the polymer represented by Formula (2A) contain a structural unit having the same main skeleton. Moreover, presumably, this is because the methylene group present in the crosslinked substance consisting of the phenol resin curing agent and the epoxy resin is protected by steric bulkiness of these polymers as described above, whereby secondary decomposition is suppressed.

As described above, if the resin composition contains, as main components, the polymer represented by Formula (1A) as the phenol resin curing agent and the polymer represented by Formula (2A) as the epoxy resin, both the increase of Tg of the cured material of the resin composition and decrease of the weight reduction rate of the cured material can be realized. As a result, the cured material obtained by curing the resin composition can exhibit excellent adhesiveness, electric stability, flame retardancy, moldability, particularly, continuous moldability, and heat resistance. Particularly, regarding the heat resistance, increase of Tg and decrease of weight reduction can be compatible with each other.

Specifically, if the resin composition is constituted as above, a glass transition temperature (Tg) of the cured material thereof can be set to be preferably equal to or higher than 180° C., more preferably equal to or higher than 200° C. and equal to or lower than 300° C., and even more preferably equal to or higher than 220° C. and equal to or lower than 250° C. Moreover, when the cured material is heated at 200° C. for 1,000 hours in the atmosphere, the weight reduction rate thereof can be set to be preferably equal to or lower than 0.3%, more preferably equal to or higher than 0.07% and equal to or lower than 0.25%, and even more preferably equal to or higher than 0.07% and equal to or lower than 0.2%. If the Tg and weight reduction rate of the cured material can be set within the above range, the resin-cured material does not easily deteriorate even at a high temperature. Accordingly, the resin composition can be used as a semiconductor encapsulating material of a package equipped with a semiconductor element such as SiC or GaN.

The weight reduction rate of the cured material can be measured by, for example, the following method. First, a discoid test piece made of the resin composition is formed, and the test piece is cured for 4 hours at 175° C. Thereafter, the test piece is dried for 20 hours at 125° C. and cooled. Subsequently, the weight thereof is measured, and the initial weight thereof is determined. Next, the test piece is put into a high-temperature bath of 200° C. in the atmosphere and heated for 1,000 hours, followed by cooling.

Thereafter, the weight thereof is measured to determine a post-process weight. By determining a ratio of the weight obtained after the process to the initial weight, the weight reduction rate can be calculated.

In an embodiment of the present invention, provided that a content of the phenol resin curing agent represented by Formula (1A) in the resin composition is Al (% by mass), and a content of the epoxy resin represented by Formula (2A) in the resin composition is A2 (% by mass), the value of A1/(A1+A2) is preferably equal to or greater than 0.2 and equal to or less than 0.9, and more preferably equal to or greater than 0.3 and equal to or less than 0.7. If the value is within the above range, the number of crosslinking points formed of the glycidyl ether groups and the hydroxyl groups is adjusted within an appropriate range, whereby Tg of the cured material can be more reliably increased.

In an embodiment of the present invention, a lower limit of the hydroxyl equivalent of the phenol resin curing agent represented by Formula (1A) is set to equal to or higher than 90 g/eq, and more preferably equal to or higher than 100 g/eq. Moreover, an upper limit of the hydroxyl equivalent is set to be preferably equal to or lower than 190 g/eq, more preferably equal to or lower than 180 g/eq, and even more preferably equal to or lower than 170 g/eq.

Moreover, in an embodiment of the present invention, upper and lower limits of the epoxy equivalent of the epoxy resin represented by Formula (2A) are preferably theoretical values that are yielded when the hydroxyl groups of the phenol resin curing agent represented by Formula (1A) are substituted with the glycidyl ether groups.

In an embodiment of the present invention, when the epoxy resin represented by Formula (2A) is partially not epoxylated, that is, when a glycidyl ether group and a hydroxyl group are bonded to a benzene ring in the epoxy resin, the epoxy equivalent of such an epoxy resin is preferably equal to or more than 50%, and more equal to or more than 70% of the above theoretical value. If the epoxy equivalent is within the above range, the effects of the present invention can be exhibited. Specifically, a lower limit of the epoxy equivalent of the epoxy resin represented by Formula (2A) is set to be preferably equal to or higher than 150 g/eq, more preferably equal to or higher than 160 g/eq, and even more preferably equal to or higher than 170 g/eq. Moreover, an upper limit of the epoxy equivalent is set to be preferably equal to or lower than 290 g/eq, more preferably equal to or lower than 260 g/eq, and even more preferably equal to or lower than 240 g/eq. If the lower and upper limits are set within the above range, the number of crosslinking points formed by a reaction between an epoxy group and a hydroxyl group is set within an appropriate range, whereby the Tg of the cured material can be more reliably increased.

According to an embodiment of the present invention, the resin composition containing the epoxy resin represented by Formula (2A) and the release agent of which a 5% weight reduction temperature is equal to or higher than 240° C. also contains, as a curing agent, an appropriate phenol resin curing agent such as a monomer, an oligomer, or a polymer having two or more phenolic hydroxyl groups in one molecule. Accordingly, the resin composition can be used as a resin composition appropriate for encapsulating an element that is represented by an element (semiconductor element) using SiC or GaN and can operate under harsh conditions. Examples of the phenol resin curing agent include novolac-type resins such as phenol novolac-type resins, cresol novolac-type resins, and naphthol novolac-type resins; polyfunctional phenol resins such as triphenolmethane-type phenol resins; modified phenol resins such as terpene-modified phenol resins and dicyclopentadiene-modified phenol resins; aralkyl-type resins such as phenol aralkyl resins having a phenylene skeleton and/or a biphenylene skeleton and naphthol aralkyl resins having a phenylene and/or biphenylene skeleton; bisphenol compounds such as bisphenol A and bisphenol F; and the like. One kind of these may be used singly, or two or more kinds thereof may be used concurrently. Among these, in view of curability, phenol resin curing agents having a hydroxyl equivalent of equal to or more than 90 g/eq and equal to or less than 250 g/eq are preferable.

(Release Agent)

As described above, if the phenol resin curing agent represented by Formula (1A) and the epoxy resin represented by Formula (2A) are used, increase of Tg and decrease of weight reduction can be compatible with each other in the obtained resin composition. However, as an embodiment in which both the high temperature storage life and high temperature operating life are extremely excellent, a resin composition, which contains the epoxy resin represented by Formula (2A) and the release agent of which a 5% weight reduction temperature is equal to or higher than 240° C., or a resin composition, which contains the release agent of which a 5% weight reduction temperature is equal to or higher than 240° C., the phenol resin curing agent represented by Formula (1A), and the epoxy resin represented by Formula (2A), is exemplified. The 5% weight reduction temperature is a temperature at which 5% of the initial weight of the release agent is reduced when the release agent is heated from room temperature at a temperature increase rate of 10° C./min under a nitrogen gas flow by using a thermogravimetry and differential thermal analyzer (TG•DTA). When the 5% weight reduction temperature is equal to or higher than 240° C., it means that the temperature at which 5% of the initial weight of the release agent is reduced under the above measurement conditions is equal to or higher than 240° C.

The release agent refers to a substance that functions to make a molded article released from a mold when molding is performed using a transfer molding machine or the like.

The resin composition, which contains the epoxy resin represented by Formula (2A) and the release agent of which a 5% weight reduction temperature is equal to or higher than 240° C., or the resin composition, which contains the phenol resin curing agent represented by Formula (1A), the epoxy resin represented by Formula (2A), and the release agent of which a 5% weight reduction temperature is equal to or higher than 240° C., exhibits extremely excellent reliability when being subjected to a test for high temperature storage life and high temperature operating life of an electronic device. The following is considered to be the reason, though it is not a definite reason. That is, at a high temperature, the release agent of which a 5% weight reduction temperature is equal to or higher than 240° C., the phenol resin curing agent represented by Formula (1A), and the epoxy resin represented by Formula (2A) may exert influence on one another in combination, and the synergistic effect may exert influence on an interface between the semiconductor element and the cured material of the resin composition, or on an interface between a bonding pad or a bonding wire and the cured material of the resin composition. Accordingly, reliability of the electronic device may be improved.

The release agent of the present invention of which a 5% weight reduction temperature is equal to or higher than 240° C. is not particularly limited, as long as it is a release agent known to those skilled in the art in the field of resin composition for encapsulating a semiconductor and has a 5% weight reduction temperature of equal to or higher than 240° C. Examples thereof include polyolefin wax (for example, polyethylene or polypropylene obtained by polymerizing olefin such as ethylene or propylene); polyolefin-based copolymers (for example, a copolymer composed of maleic anhydride and 1-alkene having 28 to 60 carbon atoms, a copolymer which is composed of olefin and maleic anhydride and includes esterified substances or derivatives of the above copolymer, and esterified substances or derivatives thereof); oxidized polyolefin wax or derivatives thereof (for example, oxidized polyethylene wax obtained by oxidizing a terminal double bond and the like of polyethylene, and urethane-modified polyethylene wax obtained by modifying the oxidized polyethylene with an isocyanate group-containing compound); higher fatty acid ester (for example, montanoic acid ester); and higher fatty acid amide (for example, compounds obtained by amidating higher fatty acid with an ammonia-containing amine compound), but the release agent is not limited to these. As the higher fatty acid ester, synthetic higher fatty acid ester is preferable. One kind of these release agents can be used singly, or two or more kinds thereof can be used in combination.

The lower limit of the proportion of the release agent in the entire resin composition is preferably equal to or higher than 0.01% by mass, more preferably equal to or higher than 0.05% by mass, and particularly preferably equal to or higher than 0.1% by mass. If the lower limit of the proportion of the release agent mixed in is within the above range, the cured material can be released from a mold at the time of molding. The upper limit of the release agent mixed in is preferably equal to or lower than 1.0% by mass, more preferably equal to or lower than 0.8% by mass, and particularly preferably equal to or lower than 0.5% by mass in the entire resin composition. If the upper limit of the proportion of the release agent mixed in is within the above range, an effect known in the related art, which makes it possible to inhibit contamination caused by the release agent oozing out onto the surface of a molded article, is produced. Particularly, if the proportion of the release agent mixed in is within a range of equal to or higher than 0.07% by mass and equal to or lower than 0.50% by mass, and most preferably within a range of equal to or higher than 0.11% by mass and equal to or lower than 0.45% by mass in the entire resin composition, a remarkable effect is obtained in regard to high temperature storage life and high temperature operating life of an electronic device.

(Other Components)

The resin composition of the present invention can optionally contain the following components, in addition to the phenol resin curing agent represented by Formula (1A), the epoxy resin represented by Formula (2A), and the release agent of which a 5% weight reduction temperature is equal to or higher than 240° C.

(Inorganic Filler)

An inorganic filler functions to decrease the amount of moisture that is further absorbed as the resin composition is cured and to reduce deterioration of strength. As the inorganic filler, it is possible to use inorganic fillers that are generally used in the related art.

Specifically, examples of the inorganic filler include crushed molten silica, molten spherical silica, crystalline silica, alumina, silicon nitride, aluminum nitride, and the like. These may be used singly or used by being mixed with each other.

From the viewpoint of filling properties of the inorganic filler filled in a molding cavity, an average particle size of the inorganic filler is preferably equal to or greater than 0.01 μm and equal to or less than 150 μm. The average particle size can be measured using a laser diffraction-scattering type particle size distribution analyzer.

The lower limit of the amount of the inorganic filler in the resin composition is preferably equal to or higher than 75% by mass, more preferably equal to or higher than 80% by mass, and even more preferably equal to or higher than 85% by mass, with respect to the total mass of the resin composition. If the lower limit is within the above range, a cured material exhibiting excellent solder cracking resistance can be obtained. Moreover, since the proportion of the resin is relatively reduced, an effect that makes it possible to reduce the weight reduction rate can be obtained. In addition, the interface of the cured material of the resin composition of the present invention that comes into contact with the semiconductor element can be hardened appropriately, and accordingly, not only excellent high temperature storage life which is a main object of the present invention but also high temperature operating life can be obtained.

The upper limit of the amount of the inorganic filler in the resin composition is preferably equal to or lower than 93% by mass, more preferably equal to or lower than 91% by mass, and even more preferably equal to or lower than 90% by mass with respect to the total mass of the resin composition. If the upper limit is within the above range, the obtained resin composition can exhibit excellent fluidity and moldability, and can have appropriate flexibility. Accordingly, not only excellent high temperature storage life which is a main object of the present invention but also high temperature operating life can be obtained.

In the present invention, from the viewpoint of filing properties of the inorganic filler filled in a mold cavity, an average particle size of the inorganic filler is preferably equal to or greater than 0.01 μm and equal to or less than 150 μm. It is preferable for the composition to contain spherical silica having an average particle size of equal to or greater than 7 μm and equal to or less than 50 μm, preferably in an amount of equal to or more than 60% by mass and equal to or less than 85% by mass, and more preferably in an amount of equal to or more than 65% by mass and equal to or less than 83% by mass. Within the above range, the resin composition sufficiently adheres to a semiconductor element at a high temperature and does not apply high stress to the element. Accordingly, not only excellent high temperature storage life which is a main object of the present invention but also high temperature operating life can be obtained.

In the present invention, the amount of the spherical silica having an average particle size of equal to or greater than 0.1 μm and equal to or less than 6 μm contained in the composition is preferably equal to or more than 1% by mass and equal to or less than 25% by mass, and more preferably equal to or more than 3% by mass and equal to or less than 20% by mass. Within the above range, the resin composition sufficiently adheres to a semiconductor element at a high temperature and does not apply high stress to the element. Accordingly, not only excellent high temperature storage life, which is a main object of the present invention, but also high temperature operating life can be obtained.

Moreover, in the present invention, if the composition further contains spherical silica having an average particle size of equal to or greater than 0.1 μm and equal to or less than 6 μm in an amount of equal to or more than 60% by mass and equal to or less than 85% by mass, in addition to the spherical silica having an average particle size of equal to or greater than 7 μm and equal to or less than 50 μm in an amount of equal to or more than 1% by mass and equal to or less than 25% by mass, the resin composition sufficiently adheres to a semiconductor element at a high temperature and does not apply high stress to the element. Accordingly, not only excellent high temperature storage life, which is a main object of the present invention, but also high temperature operating life can be obtained.

When a metal hydroxide, which will be described later, such as aluminum hydroxide or magnesium hydroxide, or an inorganic flame retardant such as zinc borate, zinc molybdate, or antimony trioxide is used, it is preferable to control the total amount of the inorganic flame retardant and the inorganic filler to fall within the above range.

(Curing Accelerator)

A curing accelerator functions to accelerate a reaction between an epoxy group of the epoxy resin and a hydroxyl group of the phenol resin curing agent. As the curing accelerator, it is possible to use curing accelerators that are generally used in the related art.

Specific examples of the curing accelerator include phosphorus atom-containing compounds such as organic phosphine, tetra-substituted phosphonium compounds, phosphobetaine compounds, adducts composed of a phosphine compound and a quinone compound, and adducts composed of a phosphonium compound and a silane compound; amidines or tertiary amines including, for example, 1,8-diazabicyclo(5,4,0)undecene-7, benzyl dimethyl amine, 2-methylimidazole, and the like; and nitrogen atom-containing compounds such as quaternary salts of the above amidines and amines. One kind of these curing accelerators can be used singly, or two or more kinds thereof can be used in combination. Among these, from the viewpoint of curability, the phosphorus atom-containing compounds are preferable. From the viewpoint of soldering resistance and fluidity, the phosphobetaine compounds and the adducts composed of a phosphine compound and a quinone compound are particularly preferable. Moreover, the phosphorus atom-containing compounds such as tetra-substituted phosphonium compounds and adducts composed of a phosphonium compound and a silane compound are particularly preferable, since these slightly contaminate a mold during continuous molding.

Examples of the organic phosphine usable in the resin composition include primary phosphines such as ethyl phosphine and phenyl phosphine; secondary phosphines such as dimethyl phosphine and diphenyl phosphine; and tertiary phosphines such as trimethyl phosphine, triethyl phosphine, tributyl phosphine, and triphenyl phosphine.

Examples of the tetra-substituted phosphonium compound usable in the resin composition include a compound represented by Formula (6).

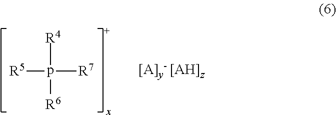

(In Formula (6), P represents a phosphorus atom; R⁴, R⁵, R⁶, and R⁷ represent aromatic groups or alkyl groups; A represents an anion of aromatic organic acid having an aromatic ring bonded to at least one functional group selected from a hydroxyl group, a carboxyl group, and a thiol group; AH represents an aromatic organic acid having an aromatic ring bonded to at least one functional group selected from a hydroxyl group, a carboxyl group, and a thiol group; x and y are numbers of 1 to 3; z is a number of 0 to 3; and x=y.)

The compound represented by Formula (6) is obtained by the following method for instance, but is not limited thereto. First, a tetra-substituted phosphonium halide, and aromatic organic acid, and a base are mixed into an organic solvent and evenly mixed with each other, such that aromatic organic acid anions are generated in the solution. If water is then added thereto, the compound represented by Formula (6) can be precipitated. In the compound represented by Formula (6), R⁴, R⁵, R⁶, and R⁷ bonded to phosphorus atoms are preferably phenyl groups; AH is preferably a compound having a hydroxyl group in an aromatic ring, that is, phenols; and A is preferably an anion of the phenols. Examples of the phenols of the present invention include monocyclic phenols such as phenol, cresol, resorcinol, and catechol; condensed polycyclic phenols such as naphthol, hydroxynaphthalene, and anthraquinone; bisphenols such as bisphenol A, bisphenol F, and bisphenol S; polycyclic phenols such as phenyl phenol and biphenol; and the like.

Examples of the phosphobetaine compounds include a compound represented by Formula (7) and the like.

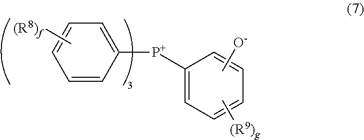

(In Formula (7), R⁸ represents an alkyl group having 1 to 3 carbon atoms; R⁹ represents a hydroxyl group; f is an integer of 0 to 5; and g is an integer of 0 to 3.)

The compound represented by Formula (7) is obtained by the following process for instance. In the process, first, tri-aromatic substituted phosphine, which is a tertiary phosphine, is brought into contact with a diazonium salt, such that the tri-aromatic substituted phosphine is substituted with a diazonium group contained in the diazonium salt. However, the process is not limited to this manner.

Examples of the adducts composed of a phosphine compound and a quinone compound include a compound represented by Formula (8) and the like.

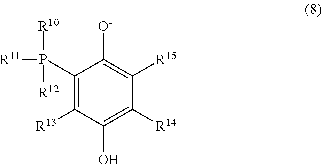

(In Formula (8), P represents a phosphorus atom; R¹⁰, R¹¹, and R¹² represent alkyl groups having 1 to 12 carbon atoms or aryl groups having 6 to 12 carbon atoms, and may be the same as or different from each other; R¹³, R¹⁴, and R¹⁵ represent hydrogen atoms or hydrocarbon groups having 1 to 12 carbon atoms, and may be the same as or different from each other; and R¹⁴ and R¹⁵ may form a cyclic group by being bonded to each other.)

As the phosphine compound used for the adducts composed of a phosphine compound and a quinone compound, phosphine compounds having an unsubstituted aromatic ring or having an aromatic ring containing a substituent such as an alkyl group or an alkoxy group, such as triphenylphosphine, tris(alkylphenyl)phosphine, tris(alkoxyphenyl)phosphine, trinaphthylphosphine, and tris(benzyl)phosphine are preferable. Examples of the substituent such as an alkyl group or an alkoxy group include alkyl and alkoxy groups having 1 to 6 carbon atoms. In view of availability, triphenylphosphine is preferable.

Examples of the quinone compound used for the adducts composed of a phosphine compound and a quinone compound include benzoquinones and anthraquinones. Among these, in view of storage stability, p-benzoquinone is preferable.

The adducts composed of a phosphine compound and a quinone compound can be produced by a method in which an organic tertiary phosphine and benzoquinones are brought into contact and mixed with each other in a solvent that can dissolve both the organic tertiary phosphine and benzoquinones. The solvent is preferably ketones such as acetone or methyl ethyl ketone in which the adduct exhibits low solubility, but the solvent is not limited thereto.

The compound represented by Formula (8) is preferably a compound in which R¹⁰, R¹¹, and R¹² bonded to phosphorus atoms are phenyl groups, and R¹³, R¹⁴, and R¹⁵ are hydrogen atoms. That is, the compound is preferably an adduct composed of 1,4-benzoquinone and triphenylphosphine, since this compound reduces a thermal elastic modulus of the cured material of the resin composition.

Examples of the adducts composed of a phosphonium compound and a silane compound include a compound represented by Formula (9) and the like.

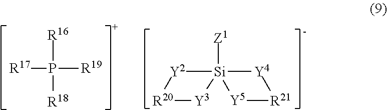

(In Formula (9), P represents a phosphorus atom; Si represents a silicon atom; each of R¹⁶, R¹⁷, R¹⁸, and R¹⁹ represents an organic group having an aromatic ring or a heterocycle or represents an aliphatic group, and may be the same as or different from each other; R²⁰ is an organic group bonded to groups Y² and Y³; R²¹ is an organic group bonded to groups Y⁴ and Y⁵; Y² and Y³ represent groups formed when a proton-donating group releases proton; the groups Y² and Y³ in the same molecule form a chelate structure by being bonded to silicon atoms; Y⁴ and Y⁵ represent groups formed when a proton-donating group releases protons; the groups Y⁴ and Y⁵ in the same molecule form a chelate structure by being bonded to silicon atoms; R²⁰ and R²¹ may be the same as or different from each other; Y², Y³, Y⁴, and Y⁵ may be the same as or different from each other; and Z¹ represents an organic group having an aromatic ring or a heterocycle or represents an aliphatic group.)

Examples of R¹⁶, R¹⁷, R¹⁸, and R¹⁹ in Formula (9) include a phenyl group, a methylphenyl group, a methoxyphenyl group, a hydroxyphenyl group, a naphthyl group, a hydroxynaphthyl group, a benzyl group, a methyl group, an ethyl group, an n-butyl group, an n-octyl group, a cyclohexyl group, and the like. Among these, aromatic groups having substituents like an alkyl group, an alkoxy group, a hydroxyl group, and the like, such as a phenyl group, a methylphenyl group, a methoxyphenyl group, a hydroxyphenyl group, and a hydroxynaphthyl group, or unsubstituted aromatic groups are more preferable.

In Formula (9), R²⁰ is an organic group boned to Y² and Y³. Similarly, R²¹ is an organic group bonded to groups Y⁴ and Y⁵. Y² and Y³ are groups formed when a proton-donating groups releases protons. Y² and Y³ in the same molecule form a chelate structure by being bonded to silicon atoms. Similarly, Y⁴ and Y⁵ are groups formed when a proton-donating group releases protons. Y⁴ and Y⁵ in the same molecule form a chelate structure by being bonded to silicon atoms. The groups R²⁰ and R²¹ may be the same as or different from each other, and the groups Y², Y³, Y⁴, and Y⁵ may be the same as or different from each other. Groups represented by —Y²—R²⁰—Y³— and —Y⁴—R²¹—Y⁵— in Formula (9) are constituted with a group that is formed when a proton-donating compound releases two protons. The proton-donating compound is preferably an organic acid having at least two carboxyl groups or hydroxyl groups in a molecule, more preferably an aromatic compound having at least two carboxyl groups or hydroxyl groups on carbon atoms which form an aromatic ring and are adjacent to each other, and even more preferably an aromatic compound having at least two hydroxyl groups on carbon atoms which form an aromatic ring and are adjacent to each other. Examples of the proton-donating compound include catechol, pyrogallol, 1,2-dihydroxynaphthalene, 2,3-dihydroxynaphthalene, 2,2′-biphenol, 1,1′-bi-2-naphthol, salicylic acid, 1-hydroxy-2-naphthoic acid, 3-hydroxy-2-naphthoic acid, chloranilic acid, tannic acid, 2-hydroxybenzylalcohol, 1,2-cyclohexanediol, 1,2-propanediol, glycerin, and the like. Among these, catechol, 1,2-dihydroxynaphthalene, and 2,3-dihydroxynaphthalene are more preferable.

Z¹ in Formula (9) represents an organic group having an aromatic ring or a heterocycle or represents an aliphatic group. Specific examples thereof include aliphatic hydrocarbon groups such as a methyl group, an ethyl group, a propyl group, a butyl group, a hexyl group, and an octyl group and the like; aromatic hydrocarbon groups such as a phenyl group, a benzyl group, a naphthyl group, and a biphenyl group and the like; reactive substituents such as an alkyl group or a vinyl group having a glycidyloxy group, a mercapto group, or an amino group such as a glycidyloxy propyl group, a mercaptopropyl group, and an aminopropyl group and the like. Among these, in view of thermal stability, a methyl group, an ethyl group, a phenyl group, a naphthyl group, and a biphenyl group are more preferable.

In a method for producing the adduct composed of a phosphonium compound and a silane compound, a silane compound such as phenyltrimethoxysilane and a proton-donating compound such as 2,3-dihydroxynaphthalene are put into a flask containing methanol and dissolved, and then a sodium methoxide methanol solution is added dropwise thereto under stirring at room temperature. Thereafter, a solution, which is prepared in advance by dissolving a tetra-substituted phosphonium halide such as tetraphenyl phosphonium bromide in a methanol, is added dropwise to the above solution under stirring at room temperature, whereby crystals are precipitated. The precipitated crystals are filtered, washed with water, and dried in a vacuum, whereby an adduct composed of a phosphonium compound and a silane compound is obtained. However, the method is not limited to the above.

Preferable curing accelerators of the present invention include the compounds represented by Formulae (6) to (9). Among these, adducts composed of a phosphine compound and a quinone compound and adducts composed of a phosphonium compound and silane compound are particularly preferable, since these make the resin composition sufficiently adhere to a semiconductor element at a high temperature. The following is considered to be the reason, though it is not a definite reason. That is, the phenol resin curing agent represented by Formula (1A), or the aromatic group, which has plural hydroxyl groups and contained in the epoxy resin represented by Formula (2A), and the curing accelerator may show unique behavior in the interface of a semiconductor element when the resin composition is cured or when the element operates at a high temperature, and as a result, the obtained semiconductor element may have not only excellent high temperature storage life but also high temperature operating life.

The proportion of the curing accelerator mixed in is preferably equal to or higher than 0.1% by mass and equal to or lower than 1% by mass of the entire resin composition. If the proportion of the curing accelerator mixed in is within the above range, sufficient curability and fluidity can be obtained.

When the curing accelerator produces the above effects that have been known in the related art, and the curing accelerator is mixed into the resin composition of the present invention in a proportion of equal to or higher than 0.11% by mass and equal to or lower than 0.70% by mass and most preferably in a proportion of equal to or higher than 0.12% by mass and equal to or lower than 0.65% by mass, a special effect that makes the electronic element have not only excellent high temperature storage life but also high temperature operating life is obtained.

Up to now, particularly important components of the present invention have been described. However, in the present invention, when the aforementioned release agent, inorganic filler, and curing accelerator are combined with each other as described in the aforementioned preferable embodiment in the resin composition, which contains the phenol resin curing agent represented by Formula (1A), the epoxy resin represented by Formula (2A), and the release agent of which a 5% weight reduction temperature is equal to or higher than 240° C., not only excellent high temperature storage life, which is a main object of the present invention, but also high temperature operating life become optimal.

(Compound in Which Each of Two or More Carbon Atoms Constituting an Aromatic Ring and Adjacent to Each Other is Bonded to a Hydroxyl Group)

If a compound (A) in which each of two or more carbon atoms constituting an aromatic ring and adjacent to each other is bonded to a hydroxyl group (hereinafter, the compound will be simply referred to as “compound (A)” in some cases) is used, even when a phosphorus atom-containing curing accelerator not exhibiting latency is used as a curing accelerator that accelerates a crosslinking reaction between the phenol resin curing agent and the epoxy resin, it is possible to inhibit the resin composition from causing a reaction while being melted and kneaded.

If the resin composition contains the compound (A), it is preferable since an encapsulating material can be formed under higher shearing conditions, fluidity of the resin composition is improved, and an effect of reducing a cleaning cycle of a mold is obtained by inhibiting release components from rising to the surface of a package during continuous molding or being accumulated on the surface of a mold.

The compound (A) has an effect of decreasing melt viscosity and improving fluidity of the resin composition. Moreover, the compound (A) also has an effect of improving soldering resistance, though the detailed mechanism thereof is unclear.

As the compound (A), it is possible to use a monocyclic compound represented by Formula (10) or a polycyclic compound represented by Formula (11), and these compounds may have substituents other than a hydroxyl group.

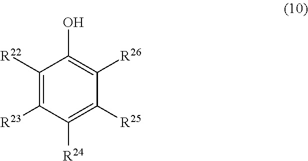

(In Formula (10), either R²² or R²⁶ is a hydroxyl group; when one of R²² and R²⁶ is a hydroxyl group, the other is a hydrogen atom, a hydroxyl group, or a substituent other than a hydroxyl group; and R²³, R²⁴, and R²⁵ are hydrogen atoms, hydroxyl groups, or substituents other than hydroxyl groups.)

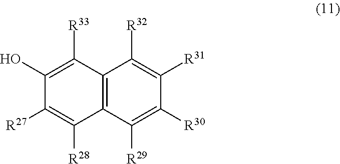

(In Formula (11), either R²⁷ or R³³ is a hydroxyl group; when one of R²⁷ and R³³ is a hydroxyl group, the other is a hydrogen atom, a hydroxyl group, or a substituent other than a hydroxyl group; and R²⁸, R²⁹, R³⁰, R³¹, and R³² are hydrogen atoms, hydroxyl groups, or substituents other than hydroxyl groups.)

Specific examples of the monocyclic compound represented by Formula (10) include catechol, pyrogallol, gallic acid, and gallic acid ester, and derivatives of these.

Specific examples of the polycyclic compound represented by Formula (11) include 1,2-dihydroxynaphthalene, 2,3-dihydroxynaphthalene, and derivatives of these. Among these, in view of ease of controlling fluidity and curability, a compound in which each of two carbon atoms constituting an aromatic ring and adjacent to each other is bonded to a hydroxyl group is preferable. Considering volatilization of the compound in a kneading process, it is preferable to use a compound which has a low-volatile naphthalene ring exhibiting a high degree of weighing stability as a mother nucleus. In this case, specifically as the compound (A), it is possible to use compounds having a naphthalene ring, such as 1,2-dihydroxynaphthalene, 2,3-dihydroxynaphthalene, and derivatives thereof. One kind of the compound (A) may be used singly, or two or more kinds thereof may be used in combination.

The proportion of the compound (A) mixed in is preferably equal to or higher than 0.01% by mass and equal to or lower than 1% by mass, more preferably equal to or higher than 0.03% by mass and equal to or lower than 0.8% by mass, and particularly preferably equal to or higher than 0.05% by mass and equal to or lower than 0.5% by mass in the entire resin composition. If the lower limit of the proportion of the compound (A) mixed in is within the above range, viscosity of the resin composition can be reduced to a sufficient degree, and a fluidity improving effect can be obtained. If the upper limit of the proportion of the compound (A) mixed in is within the above range, curability of the resin composition and physical properties of the cured material are less likely to deteriorate.

(Coupling Agent)

A coupling agent functions to improve adhesiveness between the epoxy resin and the inorganic filler when the resin composition contains the inorganic filler, and for example, a silane coupling agent and the like are used.

As the silane coupling agent, various silane coupling agents such as mercaptosilane can be used.

The lower limit of the proportion of the coupling agent such as a silane coupling agent mixed in is preferably equal to or higher than 0.01% by mass, more preferably equal to or higher than 0.05% by mass, and particularly preferably equal to or higher than 0.1% by mass in the entire resin composition. If the lower limit of the proportion of the coupling agent such as a silane coupling agent mixed in is within the above range, an electronic device can obtain excellent solder cracking resistance without decreasing interfacial strength between the epoxy resin and the inorganic filler. The upper limit of the proportion of the coupling agent such as a silane coupling agent mixed in is preferably equal to or lower than 1% by mass, more preferably equal to or lower than 0.8% by mass, and particularly preferably equal to or lower than 0.6% by mass in the entire resin composition. If the upper limit of the proportion of the coupling agent such as a silane coupling agent mixed in is within the above range, a device can obtain excellent solder cracking resistance without decreasing interfacial strength between the epoxy resin and the inorganic filler. Moreover, if the proportion of the coupling agent such as a silane coupling agent mixed in is within the range, an electronic device can obtain excellent solder cracking resistance without enhancing water-absorbing properties of the cured material of the resin composition.

(Inorganic Flame Retardant)

An inorganic flame retardant functions to improve flame retardancy of the resin composition, and as the inorganic flame retardant, inorganic flame retardants that are in general use are utilized.

Specifically, metal hydroxides that hinder a combustion reaction by causing dehydration and absorbing heat during combustion or composite metal hydroxides that can shorten the combustion time are preferably used.

Examples of the metal hydroxides include aluminum hydroxide, magnesium hydroxide, calcium hydroxide, barium hydroxide, and zirconia hydroxide.

The composite metal hydroxides may be hydrotalcite containing two or more kinds of metal elements. In the hydrotalcite, at least one of the metal elements may be magnesium, and the other metal element maybe a metal element selected from calcium, aluminum, tin, titanium, iron, cobalt, nickel, copper, and zinc. As such composite metal hydroxides, solid solutions consisting of magnesium hydroxide and zinc are easily obtained in the form of commercially available products.

Among these, from the viewpoint of balance between soldering resistance and continuous moldability, aluminum hydroxide and the solid solution consisting of magnesium hydroxide and zinc are preferable.

One kind of the inorganic flame retardant may be used singly, or two or more kinds thereof may be used. Moreover, in order to reduce the influence exerted on continuous moldability, the flame retardant may be used after being subjected to surface treatment by using a silicon compound such as a silane coupling agent, an aliphatic compound such as wax, and the like.

In the present invention, the above inorganic flame retardant may be used. However, provided that a weight of an inorganic flame retardant that is yielded when the retardant is subjected to a drying process for 20 hours at 125° C. and then cooled in a desiccators is an initial weight, and a weight of the inorganic flame retardant that is yielded when the retardant is subjected to a heating process for 1,000 hours by being put in a high-temperature chamber at 200° C. and then cooled in a desiccator is a post-process weight, if the post-process weight is reduced 0.1% by mass or more compared to the initial weight, it is preferable not to use such a flame retardant. In addition, it is desirable to constitute the resin composition only with a flame retardant resin, without using an inorganic flame retardant.

That is, in the resin composition of the present invention, both the phenol resin curing agent represented by Formula (1A) and epoxy resin represented by Formula (2A) have a biphenyl skeleton exerting a flame retarding effect. As a result, they have a high degree of flame retardancy and functions as a flame retardant. For this reason, even if a metal hydroxide-based flame retardant, which may release water at a high temperature equal to or higher than 200° C. and thus increase the weight reduction rate of the cured material, is not mixed into the resin composition, the resin composition can have the same characteristics as in the case where the flame retardant is added to the resin composition.

Further, in addition to other components described above, components known to those skilled in the art, such as colorants like carbon black, red iron oxide, and titanium oxide, may be appropriately mixed into the resin composition.

Moreover, if the phenol resin curing agent, epoxy resin, and other components are evenly mixed with each other at room temperature by using, for example, a mixer or the like, followed by melting and kneading if necessary by using a heating roller, a kneader, or a kneading machine such as an extruder, and then cooled and pulverized if necessary, dispersity, fluidity, and the like of the resin composition of the present invention can be adjusted to a desired level.

In the present embodiment, the electronic device of the present invention is not limited to the above description and can be preferably applied to semiconductor packages in various forms. For example, the electronic device can be applied not only to packages used for memories or logic elements, such as a dual in-line package (DIP), a plastic leaded chip carrier (PLCC), a quad flat package (QFP), a low-profile quad flat package (LQFP), a small outline package (SOP), a small outline J-lead package (SOJ), a thin small outline package (TSOP), a thin quad flat package (TQFP), a tape carrier package (TCP), a ball grid array (BGA), a chip size package (CSP), a matrix array package ball grid array (MAPBGA), and a chip-stacked chip size package, but also to packages such as TO-220 equipped with a power element such as a power transistor.

Up to now, the resin composition and the electronic device of the present invention have been described, but the present invention is not limited to the above description.

For example, optional components that can carry out the same function as described above may be added to the resin composition of the present invention.

Moreover, the constituents of each part of the electronic device of the present invention may be replaced with optional members that can carry out the same function as described above. Alternatively, members constituted with optional constituents may be added to the electronic device.

### EXAMPLES

Next, specific examples of the present invention will be described.

However, the present invention is not limited to the description of these examples.

1. Preparation of Raw Materials

First, raw materials used for the resin compositions of each example and comparative example will be described below.

The amount of each component mixed in is based on “part(s) by mass” unless otherwise specified.

(Phenol Resin Curing Agent 1; Synthesis of MFBA-Type Phenol)

A separable flask was equipped with a stirring device, a thermometer, a reflux condenser, and a nitrogen inlet, and 291 parts by mass of 1,3-dihydroxybenzene (manufactured by Tokyo Chemical Industry Co., Ltd., “Resorcinol”, melting point 111° C., molecular weight 110, purity 99.4%), 235 parts by mass of phenol (special-grade reagent manufactured by KANTO CHEMICAL CO., INC., “Phenol”, melting point 41° C., molecular weight 94, purity 99.3%), and 125 parts by mass of 4,4′-bischloromethylbiphenyl (manufactured by Wako Pure Chemical Industries, Ltd., “4,4′-Bischloromethylbiphenyl”, melting point 126° C., purity 95%, molecular weight 251) which had been atomized in advance were weighed and put into the separable flask. The resultant was heated under nitrogen purging, and stirred as soon as phenol started to be melted.

Thereafter, in a state where the internal temperature of the system was being kept within a range of 110° C. to 130° C., the resultant was reacted for 3 hours and then heated. Subsequently, in a state where the temperature was being kept within a range of 140° C. to 160° C., the resultant was reacted for 3 hours.

In addition, hydrochloric acid gas generated inside the system by the reaction was discharged out of the system by a nitrogen gas flow.

After the reaction ended, unreacted components were distilled away at 150° C. under a pressure reduced to 22 mmHg. Thereafter, 400 parts by mass of toluene was added thereto, evenly dissolved, and then transferred to a separating funnel. 150 parts by mass of distilled water was then added thereto, followed by shaking, and an operation for removing an aqueous layer (washing with water) was repeated until the water for washing became neutral. Next, an oil layer was depressurized at 125° C. so as to distill away volatile components such as toluene and residual unreacted components, thereby obtaining a phenol resin curing agent 1 (polymer) represented by Formula (12A). In the phenol resin curing agent 1, a hydroxyl equivalent was 135.

Moreover, an average k0 of a repeating number k of a structural unit having one hydroxyl group and an average m0 of a repeating number m of a structural unit having two hydroxyl groups were obtained by conducting arithmetical calculation, by regarding a relative intensity ratio measured and analyzed by Field Desorption Mass Spectrometry (FD-MS) as amass ratio. As a result, a ratio of k0/m0 was confirmed to be 0.98/1, and a number average molecular weight was confirmed to be 460. The number average molecular weight was measured using Alliance (2695 separations module, 2414 refractive index detector, TSK gel GMHHR-L×2+TSK guard column HHR-L×1, mobile phase: THF, 0.5 ml/min) manufactured by Waters Corporation, by performing gel permeation chromatography (GPC) under conditions of a column temperature of 40.0° C., an internal temperature of a differential refractometer of 40.0° C., and an amount of sample injected of 100 μl.

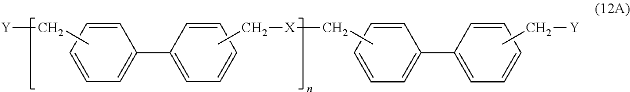

(In Formula (12), each of two Ys independently represents a hydroxyphenyl group represented by Formula (12B) or Formula (12C); and X represents a hydroxyphenylene group represented by Formula (12D) or Formula (12E).)

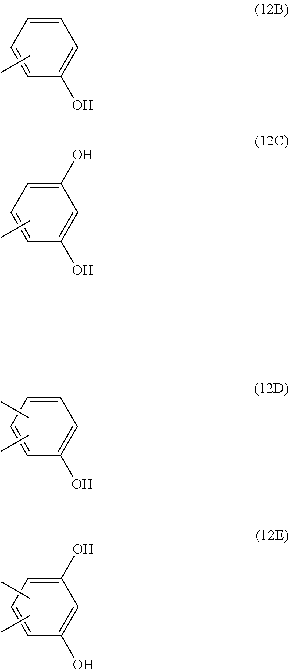

(Phenol Resin Curing Agent 2; Synthesis of MFBA-Type Phenol)

A phenol resin curing agent 2 (polymer) represented by Formula (12A) was obtained in the same manner as in the section of (Phenol Resin Curing Agent 1: Synthesis of MFBA-Type Phenol), except that resorcinol was used in an amount of 374 parts by mass, phenol was used in an amount of 141 part by mass, and 4, 4′-bischloromethylphenyl was used in an amount of 100 parts by mass. In the phenol resin curing agent 2, a hydroxyl equivalent was 120.

Moreover, an average k0 of a repeating number k of a structural unit having one hydroxyl group and an average m0 of a repeating number m of a structural unit having two hydroxyl groups were obtained by conducting arithmetical calculation, by regarding a relative intensity ratio measured and analyzed by Field Desorption Mass Spectrometry as a mass ratio. As a result, a ratio of k0/m0 was confirmed to be 0.51/1, and a number average molecular weight was confirmed to be 480.

(Phenol Resin Curing Agent 3: Preparation of BA-Type Phenol)

A phenol (having one hydroxyl group) aralkyl resin (manufactured by MEIWA PLASTIC INDUSTRIES LTD., MEH-7851SS, hydroxyl equivalent 203 g/eq) having a biphenylene skeleton was prepared.

(Phenol Resin Curing Agent 4: Preparation of TPM-Type Phenol)

A triphenylmethane-type phenol resin (manufactured by MEIWA PLASTIC INDUSTRIES LTD., MEH-7500, hydroxyl equivalent 97 g/eq) was prepared.

(Epoxy Resin 1; Synthesis of MFBA-Type Epoxy)

A separable flask was equipped with a stirring device, a thermometer, a reflux condenser, and a nitrogen inlet, and 100 parts by mass of the phenol resin curing agent 1 and 400 parts by mass of epichlorohydrin (manufactured by Tokyo Chemical Industry Co., Ltd.) were weighed and put into the flask. After the resultant was dissolved by being heated at 100° C., 60 parts by mass of sodium hydroxide (fine granular solid reagent having a purity of 99%) was slowly added thereto over 4 hours, and the resultant was reacted for 3 hours. Thereafter, 200 parts by mass of toluene was added thereto and dissolved, and then 150 parts by mass of distilled water was added thereto, followed by shaking. An operation for removing an aqueous layer (washing with water) was repeated until the water for washing became neutral, and then an oil layer was depressurized to 2 mmHg at 125° C. so as to distill away epichlorohydrin. 300 parts by mass of methyl isobutyl ketone was added to the obtained solids and dissolved, and the resultant was heated to 70° C. Subsequently, 13 parts by mass of a 30% by mass aqueous sodium hydroxide solution was added thereto over 1 hour, and then the resultant was reacted for 1 hour and allowed to standstill, and an aqueous layer was removed. An operation of washing the resultant with water was performed by adding 150 parts by mass of distilled water to an oil layer, and the operation was repeated until the water for washing became neutral. Thereafter, the resultant was heated under reduced pressure to distill away methyl isobutyl ketone, thereby obtaining an epoxy resin 1 (epoxy equivalent 200 g/eq) containing a compound represented by Formula (13A). The epoxy resin had a number average molecular weight of 560.

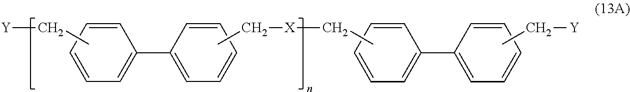

(In Formula (13A), each of two Ys independently represents a glycidylated phenyl group represented by Formula (13B) or Formula (13C); and X represents a glycidylated phenylene group represented by Formula (13D) or Formula (13E).)

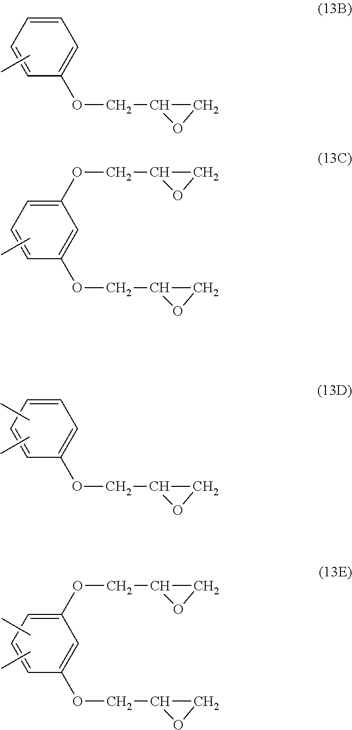

(Epoxy Resin 2; Synthesis of MFBA-Type Epoxy)

A synthesis process was performed according to the same sequence as in the case of the epoxy resin 1, except that the phenol resin curing agent 2 (120 parts by mass) was used. As a result, an epoxy resin 2 (epoxy equivalent 185 g/eq) containing the compound represented by Formula (13A) was obtained. The obtained epoxy resin 2 had a number average molecular weight of 670.

(Epoxy Resin 3; Preparation of BA-Type Epoxy)

A phenol aralkyl resin-type epoxy resin having a biphenylene skeleton (epoxy resin whose raw material is a phenol aralkyl resin in which a hydroxyl group of phenol has one biphenylene skeleton) (manufactured by Nippon Kayaku Co., Ltd., NC 3000, epoxy equivalent 276 g/eq, softening point 58° C.) was prepared.

(Epoxy Resin 4; Preparation of TPM-Type Epoxy)

A triphenylmethane-type epoxy resin (manufactured by Mitsubishi Chemical Corporation, 1032H-60, epoxy equivalent 171 g/eq, softening point 60° C.) was prepared.

(Release Agent)

As a release agent 1, an oxidized polyethylene wax (manufactured by Clariant Japan K.K., “Licowax PED191”, Td5 305° C.) was prepared.

In the present specification, “Td5 (5% weight reduction temperature)” refers to a temperature at a point in time when the weight of a release agent is reduced 5% compared to the initial weight thereof, when the release agent is heated by a thermogravimetry and differential thermal analyzer (hereinafter, abbreviated to “TG•DTA”) under a nitrogen gas flow by increasing the temperature from 30° C. to 400° C. at a rate of 10° C./min.

As a release agent 2, a urethane-modified oxidized polyethylene wax (manufactured by NIPPON SEIRO CO. , LTD. , “NPS-6010P”, Td5 262° C.) was prepared.

As a release agent 3, montanoic acid ester (manufactured by Clariant Japan K.K., “Licolub WE4”, Td5 285° C.) was prepared.

As a release agent 4, a compound obtained by esterifying a copolymer composed of maleic anhydride and 1-alkene (having 28 to 60 carbon atoms) with a stearyl alcohol was prepared.

(Method for Synthesizing Release Agent 4)

300 g of a copolymer (manufactured by Mitsubishi Chemical Corporation, trade name Diacarna (registered trademark) 30) composed of maleic anhydride and a mixture consisting of 1-octacosene, 1-triacontene, 1-tetracontene, 1-pentacontene, 1-hexacontene, and the like and 141 g of a stearyl alcohol (manufactured by Tokyo Chemical Industry Co., Ltd.) were dissolved at 100° C., and 5 g of a 10% aqueous solution of trifluoromethanesulfonic acid (manufactured by Tokyo Chemical Industry Co., Ltd.) was added dropwise thereto to cause a reaction for 8 hours at 160° C. Thereafter, the reaction was performed for 2 hours at 160° C. under reduced pressure, thereby obtaining 436 g of a release agent 4. Td5 thereof measured by TG/DTA was 270° C.

As a release agent 5, stearic acid (manufactured by NOF CORPORATION, “SR-Sakura”, Td5 220° C.) was prepared.

(Inorganic Filler 1)

As an inorganic filler 1, molten spherical silica (manufactured by DENKI KAGAKU KOGYO KABUSHIKI KAISHA, “FB560”, average particle size 30 μm) was prepared. In the present invention, the average particle size was measured using a laser diffraction•scattering particle size distribution analyzer SALD-7000 manufactured by Shimadzu Corporation.

(Inorganic Filler 2)

As an inorganic filler 2, molten spherical silica (“SO-25R” manufactured by Admatechs, average particle size 0.5 μm) was prepared.

(Curing Accelerator)

As a curing accelerator 1, a curing accelerator represented by Formula (14) was prepared.

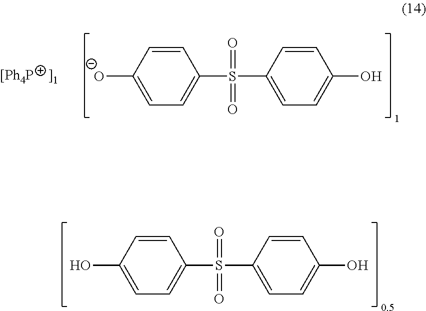

(Method for Synthesizing Curing Accelerator 1)

37.5 g (0.15 mol) of 4,4′-bisphenol S and 100 ml of methanol were put into a separable flask equipped with a stirring device and dissolved under stirring at room temperature, and to this solution, a solution that had been prepared in advance by dissolving 4.0 g (0.1 mol) of sodium hydroxide in 50 ml of methanol was added under stirring. Thereafter, a solution that had been prepared in advance by dissolving 41.9 g (0.1 mol) of tetraphenyl phosphonium bromide in 150 ml of methanol was added to the above solution. Subsequently, stirring was continued for a while, and 300 ml of methanol was added thereto. Thereafter, the solution in the flask was added dropwise to a large amount of water under stirring, thereby obtaining white precipitates. The precipitates were filtered and dried, thereby obtaining a white crystalline curing accelerator 1.

As a curing accelerator 2, a curing accelerator represented by Formula (15) was prepared.

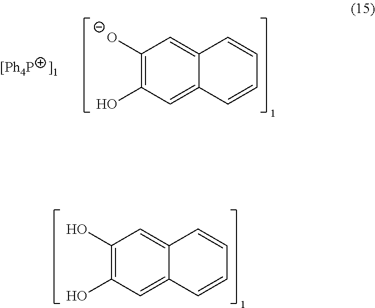

(Method for Synthesizing Curing Accelerator 2)

12.81 g (0.080 mol) of 2,3-dihydroxynaphthalene, 16.77 g (0.040 mol) of tetraphenyl phosphonium bromide, and 100 ml of methanol were put into a separable flask equipped with a cooling tube and a stirring device and evenly mixed with each other. A sodium hydroxide solution that had been prepared in advance by dissolving 1.60 g (0.04 mol) of sodium hydroxide in 10 ml of methanol was slowly added dropwise into the flask, whereby crystals were precipitated. The precipitated crystals were filtered, washed with water, and dried in a vacuum, thereby obtaining a curing accelerator 2.

As a curing accelerator 3, a curing accelerator represented by Formula (16) was prepared.

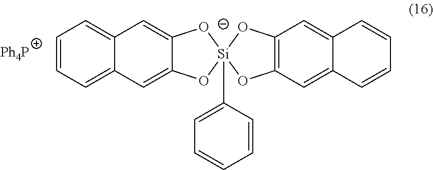

(Method for Synthesizing Curing Accelerator 3)

249.5 g of phenyltrimethoxysilane and 384.0 g of 2,3-dihydroxynaphthalene were put in a flask containing 1,800 g of methanol and dissolved, and then 231.5 g of a 28% sodium methoxide-methanol solution was added dropwise thereto under stirring at room temperature. Thereafter, a solution that had been prepared in advance by dissolving 503.0 g of tetraphenyl phosphonium bromide in 600 g of methanol was added dropwise thereto under stirring at room temperature, whereby crystals were precipitated. The precipitated crystals were filtered, washed with water, and dried in a vacuum, thereby obtaining a crystalline curing accelerator 3 which was light pink in color.

As a curing accelerator 4, a compound which is represented by Formula (17) and to which 1,4-benzoquinone and triphenylphosphine were added was prepared.

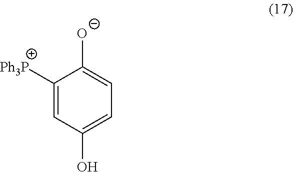

(Method for Synthesizing Curing Accelerator 4)

6.49 g (0.060 mol) of benzoquinone, 17.3 g (0.066 mol) of triphenylphosphine, and 40 ml of acetone were put into a separable flask equipped with a cooling tube and a stirring device and reacted at room temperature under stirring. The precipitated crystals were washed with acetone, followed by filtering and drying, thereby obtaining a crystalline curing accelerator 4 which was dark green in color.

As a curing accelerator 5, triphenylphosphine (manufactured by Wako Pure Chemical Industries, Ltd.) was prepared.

(Silane Coupling Agent 1)

As a silane coupling agent 1, 3-mercaptopropyltrimethoxysilane (manufactured by Shin-Etsu Chemical Co., Ltd., KBM-803) was prepared.

(Colorant 1)

As a colorant, carbon black (manufactured by Mitsubishi Chemical Corporation, “MA 600”) was prepared.

2. Production of Resin Composition

### Example 1

The epoxy resin 1 (8.75 parts by mass), the phenol resin curing agent 1 (5.14 parts by mass), the inorganic filler 1 (75.00 parts by mass), the inorganic filler 2 (10.00 parts by mass), the curing accelerator 3 (0.32 parts by mass), the silane coupling agent 1 (0.20 parts by mass), the release agent 1 (0.20 parts by mass), and the colorant 1 (0.40 parts by mass) were weighed respectively and mixed with each other by a mixer. Thereafter, the mixture was kneaded with two rolls having a surface temperature of 95° C. and 25° C. respectively, thereby obtaining a kneaded material. Subsequently, the kneaded material is cooled and then pulverized, thereby obtaining a resin composition of Example 1.

### Examples 2 to 13 and Comparative Examples 1 to 4

Resin compositions of Examples 2 to 13 and Comparative Examples 1 to 4 were obtained in the same manner as in Example 1, except that the type and amount of the raw materials mixed were changed as shown in Table 1.

3. Evaluation

The used release agent and the obtained resin composition of each of the examples and comparative examples were evaluated by the following method.

3-1. Evaluation of 5% Weight Reduction Temperature (Td5)

10 mg of a sample (release agent) was put in a Pt pan, and the weight reduced when the sample was heated from 30° C. to 400° C. at a rate of 10° C./min under a nitrogen gas flow was measured using a TG•DTA analyzer (manufactured by Seiko Instruments Inc., EXSTAR 7000). Moreover, a temperature (Td5) at the time when the initial weight of the sample was reduced by 5% was measured.

3-2. Evaluation of Spiral Flow (SF)

By using a low-pressure transfer molding machine (manufactured by Kohtaki Precision Machine Co., Ltd., “KTS-15”), the resin composition of each of the examples and comparative examples was injected into a mold for spiral flow measurement based on ANSI/ASTM D 3123-72 at 175° C. under conditions of an injection pressure of 6.9 MPa and a pressure-holding time of 120 seconds. In this manner, a flow length was measured and taken as a spiral flow.

The spiral flow is a parameter of fluidity, and the higher the value of the spiral flow is, the better the fluidity is. The unit of the spiral flow is cm. In order that the resin composition is applied to a Sic or GaN power semiconductor package so as to encapsulate the module, it is preferable for the spiral flow thereof to be equal to or greater than 60 cm.

3-3. Evaluation of Glass Transition Temperature (Tg)

The glass transition temperature of the resin composition of each of the examples and comparative examples was measured based on JIS K 7244-3.

That is, by using a transfer molding machine, the resin composition of each of the examples and comparative examples was formed into a test piece of 80 mm×10 mm×4 mm at a mold temperature of 175° C. and an injection pressure of 6.9 MPa for a curing time of 90 seconds, and the test piece was subjected to post-curing for 4 hours at 175° C. Thereafter, dynamic viscoelasticity thereof was measured (temperature increase rate: 5° C./min, frequency: 10 Hz, load: 800 g) using “DDV-25GP” manufactured by A&D Company, Limited, and a tan δ peak temperature was interpreted as a glass transition temperature.

3-4. Evaluation of Weight Reduction Rate

By using a low-pressure transfer molding machine (manufactured by Kohtaki Precision Machine Co., Ltd., “KTS-30”), the resin composition of each of the examples and comparative examples was formed into a discoid test piece having a diameter of 50 mm and a thickness of 3 mm under conditions of a mold temperature of 175° C., an injection pressure of 9.8 MPa, and a curing time of 120 seconds, and the test piece was subjected to post-curing for 4 hours at 175° C. Thereafter, the test piece was subjected to a drying process for 20 hours at 125° C. and cooled. The weight of the test piece obtained after cooling was taken as an initial weight. Subsequently, the discoid test piece was put into a high-temperature chamber at 200° C. in the atmosphere, subjected to a heating process for 1,000 hours, and cooled. The weight of the test piece obtained after cooling was taken as a post-process weight.

Table 1 describes the weight reduction rate before and after the thermal process that is expressed as a percentage.

3-5. Evaluation of Heat Resistance

By using a low-pressure transfer molding machine (manufactured by Kohtaki Precision Machine Co., Ltd., “KTS-30”), the resin composition of each of the examples and comparative examples was injection-molded under conditions of a mold temperature of 175° C., an injection time of 15 seconds, a curing time of 120 seconds, and an injection pressure of 9.8 MPa, and the resultant was subjected to post-curing for 4 hours at 175° C., thereby preparing a flame resistance test piece having a thickness of 3.2 mm.

A flame resistance test was performed on the obtained flame resistance test piece according to the standard of UL94 vertical flame test.

Table 1 shows the determined rank (class) of flame resistance.

3-6. Evaluation of High Temperature Storage Life (HTSL)

By using a transfer molding machine, a 16p SOP having a chip size of 3.5 mm×3.5 mm was molded at a mold temperature of 175° C. at a pressure of 9.8 MPa for a curing time of 2 minutes. The SOP was cured for 4 hours at 175° C. and then subjected to a high temperature storage life test at 175° C. If a value of electric resistance between wirings increased 20% compared to an initial value in a package, the package was judged to be defective, and the time taken for the package to become defective was measured and indicated by averaging the time measured from four packages. The unit thereof is hour.

3-7. Evaluation of High Temperature Operating Life (HTOL)

By using a transfer molding machine, a 16p SOP having a chip size of 3.5 mm×3.5 mm was molded at a mold temperature of 175° C. at a pressure of 9.8 MPa for a curing time of 2 minutes. The SOP was cured for 4 hours at 175° C., and then a direct current of 0.5 A was applied to both ends thereof connected to a daisy chain. The SOP was stored in this state at 175° C. which is a high temperature. If a value of electric resistance between wirings increased 20% compared to an initial value in a package, the package was judged to be defective, and the time taken for the package to become defective was measured and indicated by averaging the time measured from four packages. The unit thereof is hour.

The resin composition of each of the examples and comparative examples was evaluated as above, and the results are respectively shown in the following Table 1.

TABLE 1

| | Example | | | | | | | | |
|---|---|---|---|---|---|---|---|---|---|
| | 1 | 2 | 3 | 4 | 5 | 6 | 7 | 8 | 9 |
| Epoxy resin 1 | 8.75 | 8.75 | 8.75 | 8.75 | 8.70 | 8.77 | 8.75 | 8.62 | 14.81 |
| Epoxy resin 2 | | | | | | | | | |
| Epoxy resin 3 | | | | | | | | | |
| Epoxy resin 4 | | | | | | | | | |
| Phenol resin curing agent 1 | 5.14 | 5.14 | 5.14 | 5.14 | 5.11 | 5.16 | 5.14 | 5.29 | 9.09 |
| Phenol resin curing agent 2 | | | | | | | | | |
| Phenol resin curing agent 3 | | | | | | | | | |
| Phenol resin curing agent 4 | | | | | | | | | |
| Inorganic filler 1 | 75.00 | 75.00 | 75.00 | 75.00 | 75.00 | 75.00 | 75.00 | 75.00 | 65.00 |
| Inorganic filler 2 | 10.00 | 10.00 | 10.00 | 10.00 | 10.00 | 10.00 | 10.00 | 10.00 | 10.00 |
| Curing accelerator 1 | | | | | 0.39 | | | | |
| Curing accelerator 2 | | | | | | 0.28 | | | |
| Curing accelerator 3 | 0.32 | 0.32 | 0.32 | 0.32 | | | | | |
| Curing accelerator 4 | | | | | | | 0.31 | | |
| Curing accelerator 5 | | | | | | | | 0.30 | 0.30 |
| Silane coupling agent 1 | 0.20 | 0.20 | 0.20 | 0.20 | 0.20 | 0.20 | 0.20 | 0.20 | 0.20 |
| Release agent 1 | 0.20 | | | | 0.20 | 0.20 | 0.20 | 0.20 | 0.20 |
| Release agent 2 | | 0.20 | | | | | | | |
| Release agent 3 | | | 0.20 | | | | | | |
| Release agent 4 | | | | 0.20 | | | | | |
| Release agent 5 | | | | | | | | | |
| Colorant 1 | 0.40 | 0.40 | 0.40 | 0.40 | 0.40 | 0.40 | 0.40 | 0.40 | 0.40 |
| Spiral flow (cm) | 105 | 100 | 110 | 105 | 102 | 103 | 105 | 95 | 122 |
| Tg (° C.) | 230 | 227 | 229 | 230 | 224 | 223 | 214 | 207 | 204 |
| Weight reduction rate (%) | 0.06 | 0.07 | 0.08 | 0.08 | 0.09 | 0.09 | 0.09 | 0.09 | 0.10 |
| Flame resistance (rank of | V-0 | V-0 | V-0 | V-0 | V-0 | V-0 | V-0 | V-0 | V-0 |
| flame resistance) | | | | | | | | | |
| High temperature storage | >1000 | >1000 | >1000 | >1000 | >1000 | >1000 | >1000 | 1000 | 900 |
| life (h) | | | | | | | | | |
| High temperature | 75 | 75 | 75 | 75 | 70 | 70 | 80 | 70 | 65 |
| operating life (h) | | | | | | | | | |

| | Example | | | | Comparative Example | | | |
|---|---|---|---|---|---|---|---|---|
| | 10 | 11 | 12 | 13 | 1 | 2 | 3 | 4 |
| Epoxy resin 1 | 3.82 | 8.75 | 8.75 | | 8.70 | | | |
| Epoxy resin 2 | | | | 8.85 | | | | |
| Epoxy resin 3 | | | | | | 9.76 | 8.49 | |
| Epoxy resin 4 | | | | | | | | 9.18 |
| Phenol resin curing agent 1 | 2.25 | 5.14 | 5.14 | | 5.11 | 4.16 | | |
| Phenol resin curing agent 2 | | | | 5.00 | | | | |
| Phenol resin curing agent 3 | | | | | | | 5.44 | |
| Phenol resin curing agent 4 | | | | | | | | 4.54 |
| Inorganic filler 1 | 83.00 | 80.00 | 65.00 | 75.00 | 75.00 | 75.00 | 75.00 | 75.00 |
| Inorganic filler 2 | 10.00 | 5.00 | 20.00 | 10.00 | 10.00 | 10.00 | 10.00 | 10.00 |
| Curing accelerator 1 | | | | | 0.39 | 0.29 | 0.28 | 0.49 |
| Curing accelerator 2 | | | | | | | | |
| Curing accelerator 3 | 0.14 | 0.32 | 0.32 | 0.34 | | | | |
| Curing accelerator 4 | | | | | | | | |
| Curing accelerator 5 | | | | | | | | |
| Silane coupling agent 1 | 0.20 | 0.20 | 0.20 | 0.20 | 0.20 | 0.20 | 0.20 | 0.20 |
| Release agent 1 | 0.20 | 0.20 | 0.20 | 0.20 | | 0.20 | 0.20 | 0.20 |
| Release agent 2 | | | | | | | | |
| Release agent 3 | | | | | | | | |
| Release agent 4 | | | | | | | | |
| Release agent 5 | | | | | 0.20 | | | |
| Colorant 1 | 0.40 | 0.40 | 0.40 | 0.40 | 0.40 | 0.40 | 0.40 | 0.40 |
| Spiral flow (cm) | 94 | 95 | 106 | 93 | 110 | 130 | 140 | 80 |
| Tg (° C.) | 227 | 225 | 223 | 230 | 230 | 190 | 150 | 270 |
| Weight reduction rate (%) | 0.09 | 0.09 | 0.09 | 0.08 | 0.09 | 0.12 | 0.05 | 0.41 |
| Flame resistance | V-0 | V-0 | V-0 | V-0 | V-0 | V-0 | V-0 | V-1 |
| (rank of flame resistance) | | | | | | | | |
| High temperature storage life (h) | 1000 | 950 | 950 | >1000 | 800 | 900 | 600 | 720 |
| High temperature operating life (h) | 70 | 65 | 65 | 75 | 50 | 50 | 35 | 48 |

As shown in Table 1, in each example, it was possible to improve the glass transition temperature (Tg) of the cured material and to decrease the weight reduction rate thereof while maintaining the flame resistance and fluidity of the cured material. Moreover, the high temperature storage life and the high temperature operating life were excellent. In addition, the cured material exhibited extremely excellent reliability in a semiconductor device equipped with an element which is represented by an element (semiconductor element) using SiC or GaN and can operate under harsh conditions.

On the contrary, in Comparative Example 1, the phenol resin curing agent represented by Formula (1A) and the epoxy resin represented by Formula (2A) were used, and accordingly, a high Tg was obtained, and the weight was reduced to a smaller extent. However, in Comparative Example 1, a release agent of which a 5% weight reduction temperature of lower than 240° C. was used, and as a result, the high temperature storage life and the high temperature operating life thereof were poor compared to examples. In Comparative Example 2, only the phenol resin curing agent represented by Formula (1A) was used, and as a result, Tg was slightly lower than that of examples, and the weight was reduced more than in examples. In addition, the high temperature storage life and the high temperature operating life thereof were also poor compared to examples. In Comparative Example 3, the phenol aralkyl resin having a biphenylene skeleton (phenol aralkyl resin in which a hydroxyl group of phenol has one biphenylene skeleton) and the phenol aralkyl resin-type epoxy resin having a biphenylene skeleton (epoxy resin whose raw material is a phenol aralkyl resin in which a hydroxyl group of phenol has one biphenylene skeleton) were used. As a result, although the weight reduction rate thereof was excellent, Tg was far lower than 200° C., and the high temperature storage life and the high temperature operating life were poor. In Comparative Example 4, although Tg was high, the flame resistance, weight reduction rate, and fluidity were poor. In any of comparative examples, a high Tg, a low weight reduction rate, and high temperature storage life as well as high temperature operating life of an electronic device, which are characteristics of the present invention, could not be achieved at the same time.

1. A resin composition for encapsulation comprising:
a phenol resin curing agent represented by Formula (1A);
an epoxy resin represented by Formula (2A); and
a release agent of which a 5% weight reduction temperature is equal to or higher than 240° C., 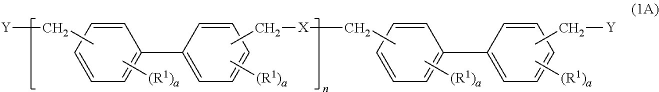
(in Formula (1A), each of two Ys independently represents a hydroxyphenyl group represented by Formula (1B) or Formula (1C); X represents a hydroxyphenylene group represented by Formula (1D) or Formula (1E); and n represents a number equal to or greater than 0. When n is equal to or greater than 2, each of two or more Xs may be independently the same as or different from each other; each of R¹s independently represents a hydrocarbon group having 1 to 5 carbon atoms; and a represents an integer of 0 to 4), 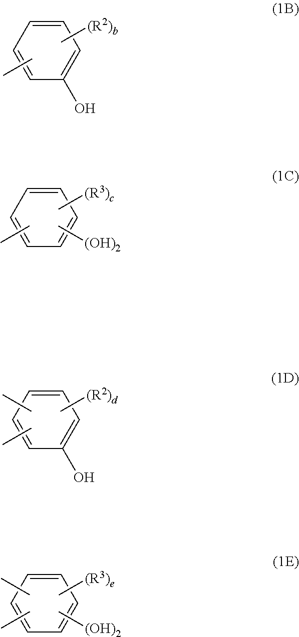
(in Formulae (1B) to (1E), each of R² and R³ independently represents a hydrocarbon group having 1 to 5 carbon atoms; b represents an integer of 0 to 4; c represents an integer of 0 to 3; d represents an integer of 0 to 3; and e represents an integer of 0 to 2), 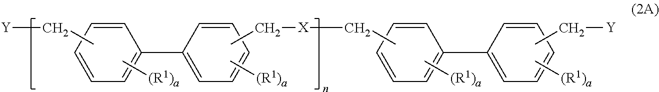
(in Formula (2A), each of two Ys independently represents a glycidylated phenyl group represented by Formula (2B) or Formula (2C); X represents a glycidylated phenylene group represented by Formula (2D) or Formula (2E); and n represents a number equal to or greater than 0. When n is equal to or greater than 2, each of two or more Xs may be independently the same as or different from each other; each of R¹s independently represents a hydrocarbon group having 1 to 5 carbon atoms; and a represents an integer of 0 to 4), 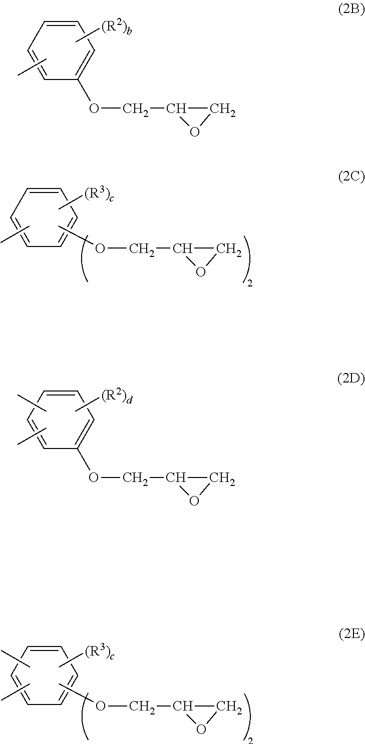
(in Formulae (2B) to (2E), each of R² and R³ independently represents a hydrocarbon group having 1 to 5 carbon atoms; b represents an integer of 0 to 4; c represents an integer of 0 to 3; d represents an integer of 0 to 3; and e represents an integer of 0 to 2).

2. The resin composition for encapsulation according to claim 1,
wherein provided that a content of the phenol resin curing agent is A1 (% by mass), and a content of the epoxy resin is A2 (% by mass), a value of A1/(A1+A2) is equal to or greater than 0.2 and equal to or less than 0.9.

3. The resin composition for encapsulation according to claim 1,
wherein a hydroxyl equivalent of the phenol resin curing agent is equal to or greater than 90 g/eq and equal to or less than 190 g/eq.

4. The resin composition for encapsulation according to claim 1,
wherein an epoxy equivalent of the epoxy resin is equal to or greater than 160 g/eq and equal to or less than 290 g/eq.

5. The resin composition for encapsulation according to claim 1, further comprising an inorganic filler.

6. The resin composition for encapsulation according to claim 1, further comprising at least one kind of curing accelerator represented by Formulae (6) to (9), 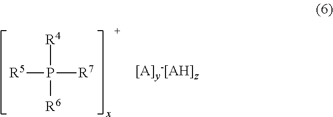
(in Formula (6), P represents a phosphorus atom; R⁴, R⁵, R⁶, and R⁷ represent aromatic groups or alkyl groups; A represents an anion of aromatic organic acid having an aromatic ring to which at least one functional group selected from a hydroxyl group, a carboxyl group, and a thiol group is bonded; AH represents an aromatic organic acid having an aromatic ring to which at least one functional group selected from a hydroxyl group, a carboxyl group, and a thiol group is bonded; x and y are 1 to 3; z is 0 to 3; and x=y), 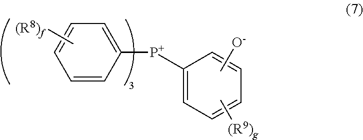
(in Formula (7), R⁸ represents an alkyl group having 1 to 3 carbon atoms; R⁹ represents an hydroxyl group; f is 0 to 5; and g is 0 to 3), 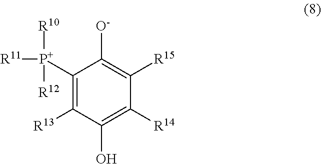
(in Formula (8), P represents a phosphorus atom; R¹⁰, R¹¹, and R¹² represent alkyl groups having 1 to 12 carbon atoms or aryl groups having 6 to 12 carbon atoms, and may be the same as or different from each other; R¹³, R¹⁴, and R¹⁵ represent hydrogen atoms or hydrocarbon groups having 1 to 12 carbon atoms, and may be the same as or different from each other; and R¹⁴ and R¹⁵ may form a cyclic group by being bonded to each other), 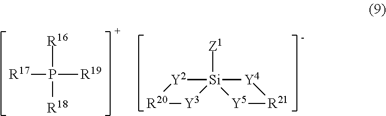
(in Formula (9), P represents a phosphorus atom; Si represents a silicon atom; each of R16, R¹⁷, R¹⁸, and R¹⁹ represents an organic group, which has an aromatic ring or a heterocycle, or an aliphatic group, and may be the same as or different from each other; R²⁰ is an organic group bonded to groups Y² and Y³; R²¹ is an organic group bonded to groups Y⁴ and Y⁵; Y² and Y³ represent groups formed when a proton-donating group releases protons; the groups Y² and Y³ in the same molecule form a chelate structure by being bonded to silicon atoms; Y⁴ and Y⁵ represent groups formed when a proton-donating group releases protons; the groups Y⁴ and Y⁵ in the same molecule form a chelate structure by being bonded to silicon atoms; R²⁰ and R²¹ may be the same as or different from each other; Y², Y³, Y⁴, and Y⁵ may be the same as or different from each other; and Z¹ is an organic group, which has an aromatic ring or a heterocycle, or an aliphatic group).

7. The resin composition for encapsulation according to claim 1, further comprising a coupling agent.

8. The resin composition for encapsulation according to claim 1,
wherein a glass transition temperature (Tg) of a cured material of the resin composition is equal to or higher than 200° C., and when the cured material is heated for 1,000 hours at 200° C. in the atmosphere, a weight reduction rate of the cured material becomes equal to or lower than 0.3%.

9. A resin composition for encapsulation comprising:
an epoxy resin represented by Formula (2A); and
a release agent of which a 5% weight reduction temperature is equal to or higher than 240° C., 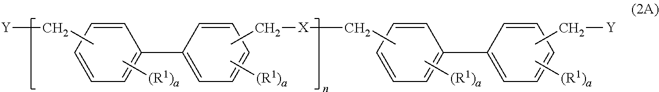
(in Formula (2A), each of two Ys independently represents a glycidylated phenyl group represented by Formula (2B) or Formula (2C); X represents a glycidylated phenylene group represented by Formula (2D) or Formula (2E); and n represents a number equal to or greater than 0. When n is equal to or greater than 2, each of two or more Xs may be independently the same as or different from each other; each of R¹s independently represents a hydrocarbon group having 1 to 5 carbon atoms; and a represents an integer of 0 to 4), 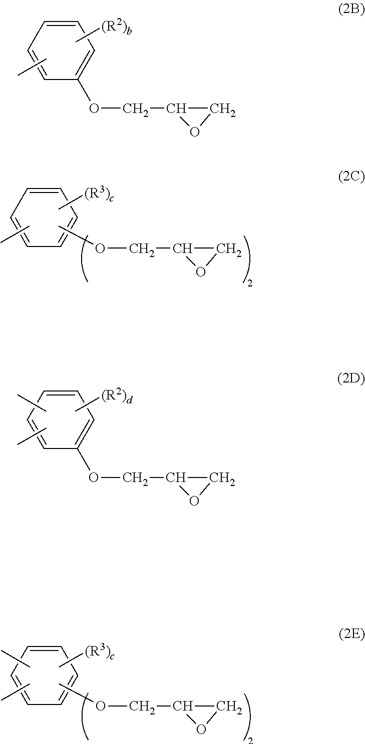
(in Formulae (2B) to (2E), each of R² and R³ independently represents a hydrocarbon group having 1 to 5 carbon atoms; b represents an integer of 0 to 4; c represents an integer of 0 to 3; d represents an integer of 0 to 3; and e represents an integer of 0 to 2).

10. The resin composition for encapsulation according to claim 9,
wherein a glass transition temperature (Tg) of a cured material of the resin composition is equal to or higher than 200° C., and when the cured material is heated for 1,000 hours at 200° C. in the atmosphere, a weight reduction rate of the cured material becomes equal to or lower than 0.3%.

11. A resin composition for encapsulation comprising:
a phenol resin curing agent;
an epoxy resin; and
a release agent of which a 5% weight reduction temperature is equal to or higher than 240° C.,
wherein a glass transition temperature (Tg) of a cured material of the resin composition is equal to or higher than 200° C., and when the cured material is heated for 1,000 hours at 200° C. in the atmosphere, a weight reduction rate of the cured material becomes equal to or lower than 0.3%.

12. The resin composition for encapsulation according to claim 11,
wherein the phenol resin curing agent is a phenol resin curing agent represented by Formula (1A), and the epoxy resin is an epoxy resin represented by Formula (2A), 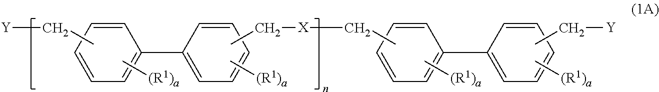
(in Formula (1A), each of two Ys independently represents a hydroxyphenyl group represented by Formula (1B) or Formula (1C); X represents a hydroxyphenylene group represented by Formula (1D) or Formula (1E); and n represents a number equal to or greater than 0. When n is equal to or greater than 2, each of two or more Xs may be independently the same as or different from each other; each of R¹s independently represents a hydrocarbon group having 1 to 5 carbon atoms; and a represents an integer of 0 to 4), 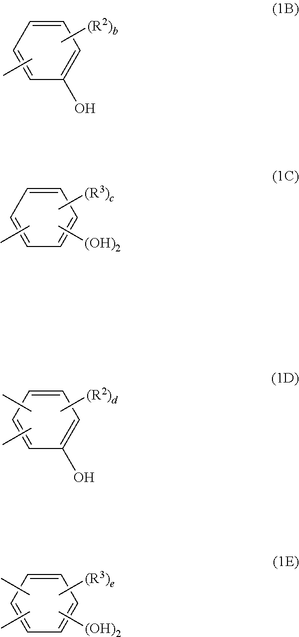
(in Formulae (1B) to (1E), each of R² and R³ independently represents a hydrocarbon group having 1 to 5 carbon atoms; b represents an integer of 0 to 4; c represents an integer of 0 to 3; d represents an integer of 0 to 3; and e represents an integer of 0 to 2), 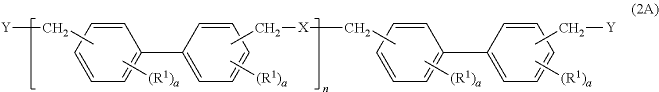
(in Formula (2A), each of two Ys independently represents a glycidylated phenyl group represented by Formula (2B) or Formula (2C); X represents a glycidylated phenylene group represented by Formula (2D) or Formula (2E); and n represents a number equal to or greater than 0. When n is equal to or greater than 2, each of two or more Xs may be independently the same as or different from each other; each of R¹s independently represents a hydrocarbon group having 1 to 5 carbon atoms; and a represents an integer of 0 to 4), 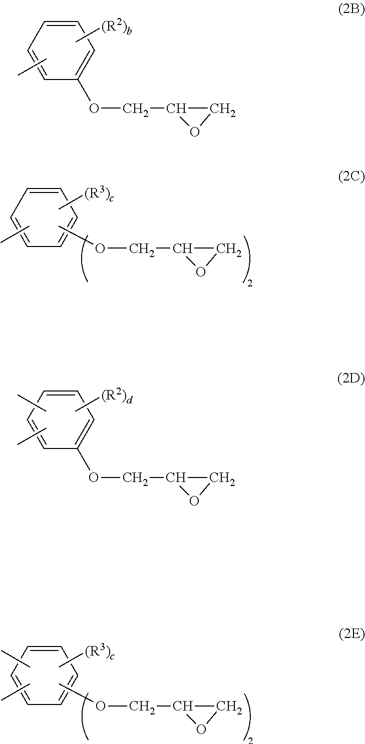
(in Formulae (2B) to (2E), each of R² and R³ independently represents a hydrocarbon group having 1 to 5 carbon atoms; b represents an integer of 0 to 4; c represents an integer of 0 to 3; d represents an integer of 0 to 3; and e represents an integer of 0 to 2).

13. An electronic device comprising an electronic component encapsulated with the resin composition for encapsulation according to claim 1.
